(19) United States
(12) Patent Application Publication
(10) Pub. No.: US 2026/0156238 A1
(43) Pub. Date: Jun. 4, 2026

(54) OPTICAL DEVICE AND ELECTRONIC DEVICE INCLUDING THE SAME

(71) Applicant: Samsung Display Co., LTD., Yongin-si (KR)

(72) Inventors: Ji Won JUNG, Yongin-si (KR); Brian CHAO, Stanford, CA (US); Gordon WETZSTEIN, Stanford (DE); Manu GOPAKUMAR, Saratoga, CA (US); Gun Yeal LEE, Palo Alto (KR); Su Yeon CHOI, Redwood City (KR)

(21) Appl. No.: 19/202,265

(22) Filed: May 8, 2025

(30) Foreign Application Priority Data
Dec. 3, 2024 (US) 63727645

(51) Int. Cl. H04N 13/332; G02F 1/1335; H10K 59/80; H10K 102/00

(52) U.S. Cl. CPC H04N 13/332; G02F 1/133524; H10K 59/875; G02F 2202/36; H10K 2102/331

(57) ABSTRACT

A display device includes a light source which provides light, a plurality of first nanostructures which collimates the light from the light source and converts a light path of the light from the light source, a light guide portion which totally reflects light incident thereon from the plurality of first nanostructures in a way such that the light travels from one end to another end thereof, a spatial light modulator which modulates a phase of light incident thereon from the light guide portion and outputs the light having the phase modulated thereby, and a plurality of second nanostructures which collimates light incident thereon from the light guide portion and converts a light path of the light incident thereon to provide the light incident thereon to the spatial light modulator.

This application claims priority to U.S. Provisional Application No. 63/727,645, filed on Dec. 3, 2024, and all the benefits accruing therefrom under 35 U.S.C. § 119, the content of which in its entirety is herein incorporated by reference.

### BACKGROUND

### 1. Field

Embodiments of the disclosure relate to an optical device and an electronic device including the optical device.

### 2. Description of the Related Art

With the development of the information society, various types of display devices have been developed to display information. For example, an augmented reality (AR) device is a display device that superimposes virtual images onto the real images seen through the user's eyes. As another example, a stereoscopic image display device is a display device that separates and displays a left-eye image and a right-eye image to allow a viewer to feel a three-dimensional effect according to binocular parallax.

### SUMMARY

In an augmented reality device or a stereoscopic image display device, a laser, whose wavefront is easily manipulated, may be mainly used as a light source. However, since the laser has poor color reproducibility and generates noise due to constructive interference, such as speckle, it may be desired for a display device to have improved color reproducibility and reduced noise.

Embodiments of the disclosure provide an optical device with improved color reproducibility and noise.

Embodiments of the disclosure also provide an electronic device including an optical device with improved color reproducibility and noise.

According to one or more embodiments of the disclosure, a display device includes a light source which provides light, a plurality of first nanostructures which collimates the light from the light source and converts a light path of the light from the light source, a light guide portion which totally reflects light incident thereon from the plurality of first nanostructures in a way such that the light incident thereon travels from one end to another end, a spatial light modulator which modulates a phase of light incident thereon from the light guide portion and outputs the light having the phase modulated thereby, and a plurality of second nanostructures which collimates light incident thereon from the light guide portion and converts a light path of the light incident thereon to provide the light of the light incident thereon to the spatial light modulator.

In an embodiment, the plurality of first nanostructures may have a first width, a first height, and a first spacing.

In an embodiment, the plurality of second nanostructures may have a second width, a second height, and a second spacing.

In an embodiment, a length of a second area, in which the plurality of second nanostructures are arranged, in a first direction may be greater than a length of a first area, in which the plurality of first nanostructures are arranged, in the first direction.

In an embodiment, a length of the second area, in which the plurality of second nanostructures are arranged, in a second direction orthogonal to the first direction may be the same as a length of the first area, in which the plurality of first nanostructures are arranged, in the second direction.

In an embodiment, the light source may be an organic light emitting diode-on-silicon (OLEDoS) display device including an organic light emitting layer disposed on a first semiconductor substrate.

In an embodiment, the light source may include a first light source which provides first light of a first color, a second light source which provides second light of a second color, and a third light source which provides third light of a third color.

In an embodiment, each of the first light source, the second light source and the third light source may be an OLEDoS display device including an organic light emitting layer disposed on a first semiconductor substrate.

In an embodiment, the plurality of first nanostructures may include a plurality of first sub-nanostructures overlapping the first light source, where the plurality of first sub-nanostructures collimates the first light emitted from the first light source and converts a light path of the first light emitted from the first light source, a plurality of second sub-nanostructures overlapping the second light source, where the plurality of second sub-nanostructures collimates the second light emitted from the second light source and converts a light path of the second light emitted from the second light source, and a plurality of third sub-nanostructures overlapping the third light source, where the plurality of third sub-nanostructures collimates the third light emitted from the third light source and converts a light path of the third light emitted from the third light source.

In an embodiment, the plurality of first sub-nanostructures and the plurality of second sub-nanostructures may be different from each other.

In an embodiment, the plurality of third sub-nanostructures may be different from the plurality of first sub-nanostructures and the plurality of second sub-nanostructures.

In an embodiment, the spatial light modulator may be a liquid crystal-on-silicon (LCoS) display device including a liquid crystal layer disposed on a second semiconductor substrate.

In an embodiment, the spatial light modulator may include a first spatial light modulator which modulates a phase of first light, a second spatial light modulator which modulates a phase of second light, and a third spatial light modulator which modulates a phase of third light.

In an embodiment, each of the first spatial light modulator, the second spatial light modulator and the third spatial light modulator may be an LCoS display device including a liquid crystal layer disposed on a second semiconductor substrate.

In an embodiment, the plurality of second nanostructures may include a plurality of fourth sub-nanostructures overlapping the first spatial light modulator, where the plurality of fourth sub-nanostructures collimates the first light incident thereon from the light guide portion and converts a light path of the first light to provide the first light incident thereon to the first spatial light modulator, a plurality of fifth sub-nanostructures overlapping the second spatial light modulator, where the plurality of fifth sub-nanostructures collimates the second light incident thereon from the light guide portion and converts a light path of the second light incident thereon to provide the second light incident thereon to the second spatial light modulator, and a plurality of sixth sub-nanostructures overlapping the third spatial light modulator, where the plurality of sixth sub-nanostructures collimates the third light incident thereon from the light guide portion and converts a light path of the third light incident thereon to provide the third light incident thereon to the third spatial light modulator.

In an embodiment, the plurality of fourth sub-nanostructures and the plurality of fifth sub-nanostructures may be different from each other.

In an embodiment, the plurality of sixth sub-nanostructures may be different from the plurality of fourth sub-nanostructures and the plurality of fifth sub-nanostructures.

In an embodiment, the light guide portion may extend in a first direction, the light source may be arranged to be adjacent to one side of the light guide portion in the first direction, and the spatial light modulator is arranged to be adjacent to another side of the light guide portion in the first direction.

In an embodiment, the light guide portion may include a first extension portion extending in a first direction, a second extension portion extending in a third direction intersecting the first direction, and a reflector arranged in an area where one side of the first extension portion and one side of the second extension portion meet.

According to one or more embodiments of the disclosure, an electronic device includes a lens, and a display device which provides an image to a user's single eye through the lens. In such embodiments, the display device includes a light source which provides light, a plurality of first nanostructures which collimates the light from the light source and converts a light path of the light from the light source, a light guide portion which totally reflects light incident thereon from the plurality of first nanostructures in a way such that the light incident thereon travels from one end to another end, a spatial light modulator which modulates a phase of light incident thereon from the light guide portion and outputs the light having the phase modulated thereby, and a plurality of second nanostructures which collimates light incident thereon from the light guide portion and converts a light path of the light incident thereon to provide the light incident thereon to the spatial light modulator.

The optical device and the electronic device including the optical device according to some embodiments of the disclosure may improve color reproducibility and light efficiency while preventing noise caused by constructive interference by using the OLEDoS display device or the LEDoS display device as the light source instead of the conventional laser.

In some embodiments, a plurality of OLEDoS display devices or a plurality of LEDoS display devices each of which emits one of first to third lights may be used as a plurality of light sources, and a plurality of first to third sub-nanostructures may be provided for each of the plurality of light sources. In such embodiments, chromatic aberration may be effectively prevented by forming the plurality of first to third sub-nanostructures to refract light while taking into account the chromatic aberration in which light is focused at different locations depending on the color during the refraction process.

In some embodiments, a plurality of spatial light modulators and a plurality of fourth to sixth sub-nanostructures may be provided for each of the first to third lights. In such embodiments, a focus for each of the first to third light may be independently formed, thereby effectively preventing the chromatic aberration.

However, the effects of the embodiments are not restricted to the one set forth herein. The above and other effects of the embodiments will become more apparent to one of daily skill in the art to which the embodiments pertain by referencing the claims.

### BRIEF DESCRIPTION OF THE DRAWINGS

The above and other features of embodiments of the disclosure will become more apparent by describing in detail embodiments thereof with reference to the attached drawings, in which:

FIG. 1 is a perspective view of an electronic device including a display device according to some embodiments of the disclosure;

FIG. 2 illustrates a head-mounted device in the form of glasses;

FIG. 3 is a front view for describing the plurality of first nanostructures of FIG. 2;

FIG. 4 is a front view for describing the plurality of second nanostructures of FIG. 2;

FIG. 5 is a plan view for describing the display device and the light guide portion of FIG. 1;

FIG. 6 is a plan view for describing the display device and the light guide portion of FIG. 1;

FIG. 7 is a plan view for describing the display device and the light guide portion of FIG. 1;

FIG. 8 is a plan view for describing the display device and the light guide portion of FIG. 1;

FIG. 9 is an exploded perspective view for describing the display device of FIG. 1;

FIG. 10 is a block diagram for describing a display panel of FIG. 9;

FIG. 11 is an equivalent circuit diagram of a first sub-pixel of FIG. 10;

FIG. 12 is a plan view for describing the display panel of FIG. 9;

FIG. 13 is a plan view for describing the display area of FIG. 12;

FIG. 14 is a plan view for describing the display area of FIG. 12;

FIG. 15 is a cross-sectional view taken along line I1-I1′ of FIG. 13, showing an embodiment of the display panel;

FIG. 16 is a cross-sectional view taken along line I1-I1′ of FIG. 13, showing another embodiment of the display panel.

### DETAILED DESCRIPTION

The invention will now be described more fully hereinafter with reference to the accompanying drawings, in which various embodiments of the invention are shown. The invention may, however, be embodied in different forms and should not be construed as limited to the embodiments set forth herein. Rather, these embodiments are provided so that this disclosure will be thorough and complete, and will fully convey the scope of the invention to those skilled in the art. The same reference numbers indicate the same components throughout the specification. In the attached drawing figures, the thickness of layers and regions is exaggerated for clarity.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

It will also be understood that when a layer is referred to as being “on” another layer or substrate, it can be directly on the other layer or substrate, or intervening layers may also be present. In contrast, when an element is referred to as being “directly on” another element, there are no intervening elements present.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” “At least one of A and B” or “at least one selected from A and B” means “A and/or B.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system).

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. A region illustrated or described as flat may, typically, have rough and/or nonlinear features, for example. Moreover, sharp angles that are illustrated may be rounded. Thus, the regions illustrated in the drawing figures are schematic in nature and their shapes are not intended to illustrate the precise shape of a region and are not intended to limit the scope of the present claims.

Hereinafter, embodiments of the disclosure will be described with reference to the accompanying drawings.

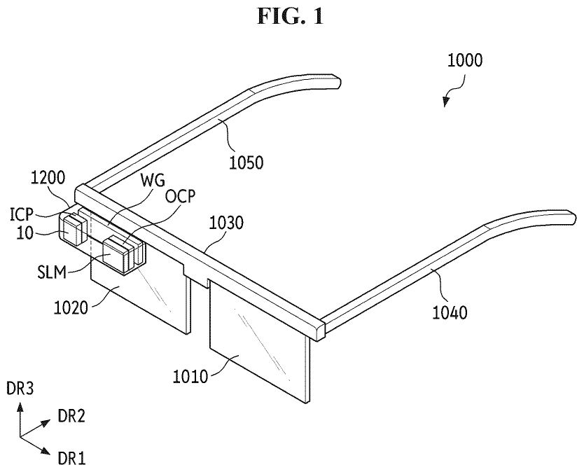

FIG. 1 is a perspective view of an electronic device including a display device according to some embodiments of the disclosure.

Referring to FIG. 1, an electronic device 1000 including a display device according to some embodiments may be a glasses-type display device in which a display device accommodating portion 1200 is implemented in a lightweight and small size. An embodiment of the electronic device 1000 including the display device may include a display device 10, a spatial light modulator SLM, a plurality of first nanostructures ICP, a plurality of second nanostructures OCP, a light guide portion WG, a left-eye lens 1010, a right-eye lens 1020, a support frame 1030, glasses frame legs 1040 and 1050, and a display device accommodating portion 1200.

The display device accommodating portion 1200 may include the display device 10, the spatial light modulator SLM, the plurality of first nanostructures ICP, the plurality of second nanostructures OCP, and the light guide portion WG. An image displayed on the display device 10 may have a path converted through the plurality of first nanostructures ICP and be incident on the light guide portion WG, an image passing through the light guide portion WG may have a path converted through the plurality of second nanostructures OCP and be incident on the spatial light modulator SLM, and an image, a phase of which is modulated in the spatial light modulator SLM, may be provided to the user's right eye through the right-eye lens 1020. Accordingly, the user may view an augmented reality image in which a virtual image displayed on the display device 10 and a real image viewed through the right-eye lens 1020 are combined through the right eye.

FIG. 1 illustrates an embodiment where the display device accommodating portion 1200 is located on one side of the support frame 1030, but the embodiment is not limited thereto. In another embodiment, for example, the display device accommodating portion 1200 may be located on the other side of the support frame 1030, and in such an embodiment, the image of the display device 10 may be provided to the user's left eye. Alternatively, the display device accommodating portion 1200 may be located on both one side and the other side of the support frame 1030. In such an embodiment, the user may view the image displayed on the display device 10 through both the user's left and right eyes.

FIG. 1 illustrates an embodiment where the electronic device 1000 including the display device is a head-mounted device in the form of glasses, but the embodiment is not limited thereto. In an embodiment, for example, the electronic device 1000 including the display device may have various forms, such as being secured to a user's head via a head-mounted band.

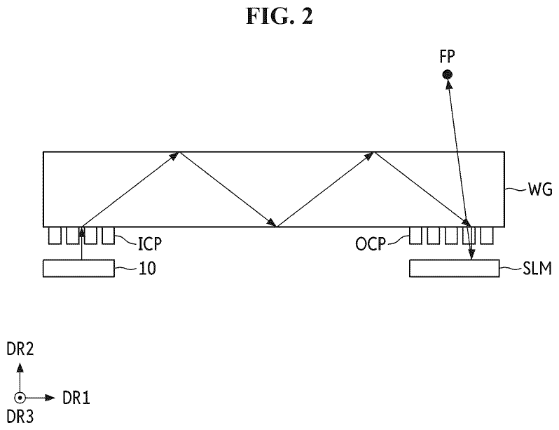

FIG. 2 is a plan view for describing the display device and the light guide portion of FIG. 1.

Referring to FIG. 2, in an embodiment, the light guide portion WG may extend in a first direction DR1. The light guide portion WG may include a material that allows light to transmit through, such as glass or plastic. The light guide portion WG may include a material having a high refractive index. In an embodiment, for example, the refractive index of the light guide portion WG may be about 2.0 or greater and about 4.1 or less.

A plurality of first nanostructures ICP may be located on one side of the light guide portion WG. Each of the plurality of first nanostructures ICP may have a size similar to a wavelength of light emitted from the display device 10. In an embodiment, the plurality of first nanostructures ICP may have a first width, a first height, and a first spacing (or interval). In an embodiment, for example, the first height of the plurality of first nanostructures ICP may be about 600 nanometers (nm), and the first spacing thereof may be about 330 nm. A phase delay of the light emitted from the display device 10 may be adjusted according to the first width of the plurality of first nanostructures ICP. In other words, an angle of refraction at which the light emitted from the display device 10 is refracted by the plurality of first nanostructures ICP may depend on the first width of the plurality of first nanostructures ICP. In an embodiment, for example, each of the plurality of first nanostructures ICP may have a cylindrical shape, but the embodiment is not limited thereto.

The plurality of first nanostructures ICP may include a material that allows light to transmit through. In an embodiment, for example, the plurality of first nanostructures ICP may include at least one selected from a silicon oxide-based material, a silicon nitride-based material, or a titanium oxide-based material.

The display device 10 may be located to be adjacent to the one side of the light guide portion WG. The display device 10 may overlap the plurality of first nanostructures ICP in a second direction DR2.

The display device 10 may be a light source that provides light. The display device 10 may provide or emit light in the second direction DR2.

In an embodiment, for example, the display device 10 may be an organic light emitting diode-on-silicon (OLEDoS) display device including an organic light emitting layer disposed on a semiconductor substrate. In another embodiment, for example, the display device 10 may be a light emitting diode (LED)-on-silicon (LEDoS) display device including an LED disposed on a semiconductor substrate, but the embodiment is not limited thereto.

A plurality of second nanostructures OCP may be located on the other side of the light guide portion WG. Each of the plurality of second nanostructures OCP may have a size similar to a wavelength of light emitted from the display device 10. In an embodiment, the plurality of second nanostructures OCP may have a second width, a second height, and a second spacing (or interval). In an embodiment, for example, the second width of the plurality of second nanostructures OCP may be about 260 nm, the second height thereof may be about 600 nm, and the second spacing thereof may be about 396 nm. In an embodiment, for example, each of the plurality of second nanostructures OCP may have a rectangular hexahedral shape, but the embodiment is not limited thereto.

The plurality of second nanostructures OCP may include a material that allows light to transmit through. In an embodiment, for example, the plurality of second nanostructures OCP may include at least one selected from a silicon oxide-based material, a silicon nitride-based material, or a titanium oxide-based material.

The spatial light modulator SLM may be located to be adjacent to the other side of the light guide portion WG. The spatial light modulator SLM may overlap the plurality of second nanostructures OCP in the second direction DR2.

The spatial light modulator SLM may modulate the phase or amplitude of light. The spatial light modulator SLM may be a reflective spatial light modulator that modulates the phase or amplitude of incident light and reflects the incident light having the modulated phase or amplitude. In an embodiment, for example, the spatial light modulator SLM may be a liquid crystal-on-silicon (LCoS) display device that includes a liquid crystal layer disposed on a semiconductor substrate, but the embodiment is not limited thereto.

The light emitted from the display device 10 may travel to the plurality of first nanostructures ICP. The light may be collimated while passing through the plurality of first nanostructures ICP. In addition, the light may have a light path converted while passing through the plurality of first nanostructures ICP. In an embodiment, for example, the light may travel in the second direction DR2, and then be refracted while passing through the plurality of first nanostructures ICP to travel in a direction where the first direction DR1 and the second direction DR2 intersect. In this case, the light may be incident on the light guide portion WG at an angle equal to or greater than a critical angle at which total reflection occurs inside the light guide portion WG.

The light totally reflected inside the light guide portion WG may pass through the plurality of second nanostructures OCP and exit the light guide portion WG to travel to the spatial light modulator SLM. The light may be phase modulated in the spatial light modulator SLM. In addition, the light may be reflected from the spatial light modulator SLM. The reflected light may be refracted while passing through the plurality of second nanostructures OCP and travel to a focus FP.

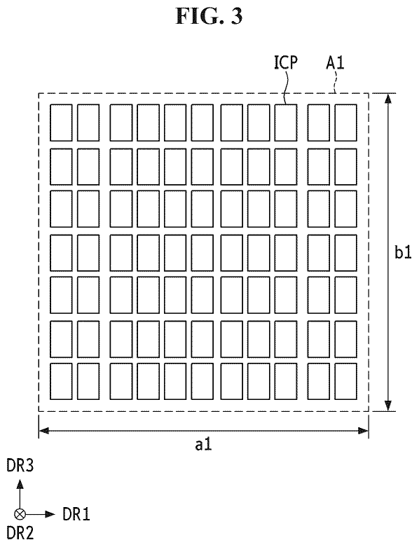

FIG. 3 is a front view for describing the plurality of first nanostructures of FIG. 2.

Referring to FIG. 3, in an embodiment, the plurality of first nanostructures ICP may be arranged in a first area A1.

The plurality of first nanostructures ICP may be uniformly or non-uniformly arranged in the first area A1. In an embodiment, for example, the first width, the first height, and the first spacing of the plurality of first nanostructures ICP positioned at a periphery of the first area A1 may be different from the first width, the first height, and the first spacing of the plurality of first nanostructures ICP positioned at the center of the first area A1.

A planar shape of the first area A1 may correspond to a planar shape of a display area of the display device 10. In an embodiment, for example, where the planar shape of the display area of the display device 10 is a circle, the planar shape of the first area A1 may also be formed as a circle. FIG. 3 illustrates an embodiment where the plane shape of the first area A1 is a square. In an embodiment, for example, a length a1 of the first area A1 in the first direction DR1 may be equal to a length b1 of the first area A1 in a third direction DR3.

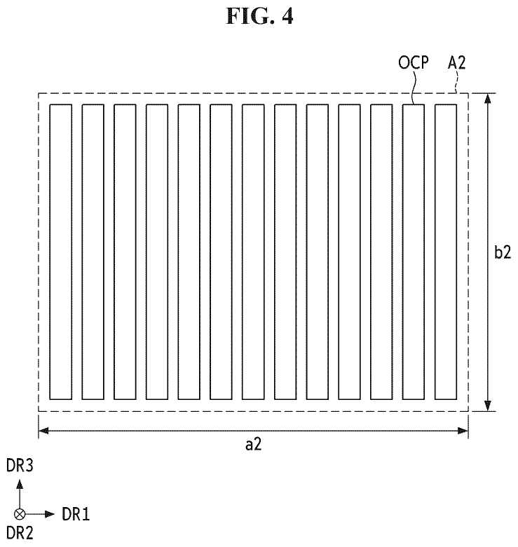

FIG. 4 is a front view for describing the plurality of second nanostructures of FIG. 2.

Referring to FIG. 4, in an embodiment, the plurality of second nanostructures OCP may be arranged in a second area A2.

The plurality of second nanostructures OCP may be uniformly or non-uniformly arranged in the second area A2. In an embodiment, for example, a second width, a second height, and a second spacing of the plurality of second nanostructures OCP positioned at a periphery of the second area A2 may be different from a second width, a second height, and a second spacing of the plurality of second nanostructures OCP positioned at the center of the second area A2.

A planar shape of the second area A2 may be different from the planar shape of the first area A1. In an embodiment, the planar shape of the second area A2 may be a rectangular shape in which a length a2 of the second area A2 in the first direction DR1 is greater than a length b2 of the second area A2 in the third direction DR3. This is because a light path is modified while light passes through the first area A1. Accordingly, the length a2 of the second area A2 in the first direction DR1 may be greater than the length a1 of the first area A1 in the first direction DR1. The length b2 of the second area A2 in the third direction DR3 may be equal to the length b1 of the first area A1 in the third direction DR3.

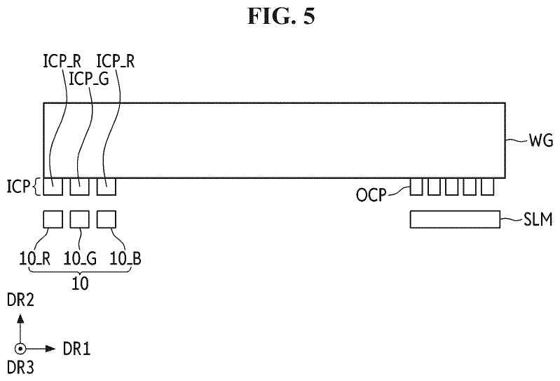

FIG. 5 is a plan view for describing the display device and the light guide portion of FIG. 1. Any repetitive detailed description of the same or like elements as those described above will be omitted or simplified, and the differences will be mainly described.

Referring to FIG. 5, the optical device according to some embodiments of the disclosure may include a first display device 10_R, a second display device 10_G, a third display device 10_B, a plurality of first sub-nanostructures ICP_R, a plurality of second sub-nanostructures ICP_G, and a plurality of third sub-nanostructures ICP_B.

In an embodiment, as shown in FIG. 2, the display device 10 may be one display device that emits all of the first light, the second light, and the third light. In another embodiment, as shown in FIG. 5, the display device 10 may include a first display device 10_R that emits first light, a second display device 10_G that emits second light, and a third display device 10_B that emits third light. In an embodiment, for example, the first light may be red light, the second light may be green light, and the third light may be blue light. The first display device 10_R, the second display device 10_G, and the third display device 10_B may each be an OLEDoS display device or an LEDoS display device.

In an embodiment, as shown in FIG. 5, the first display device 10_R and the second display device 10_G are adjacent in the first direction DR1, and the second display device 10_G and the third display device 10_B are adjacent in the first direction DR1, but the embodiment is not limited thereto. In another embodiment, for example, the first display device 10_R and the second display device 10_G may be adjacent in the third direction DR3, and the second display device 10_G and the third display device 10_B may be adjacent in the third direction DR3. In an embodiment, the first display device 10_R may be arranged to be adjacent to the third display device 10_B, and the third display device 10_B may be arranged to be adjacent to the second display device 10_G.

In an embodiment, as shown in FIG. 5, the plurality of first nanostructures ICP may include a plurality of first sub-nanostructures ICP_R, a plurality of second sub-nanostructures ICP_G, and a plurality of third sub-nanostructures ICP_B.

The plurality of first sub-nanostructures ICP_R may overlap the first display device 10_R in the second direction DR2. The plurality of first sub-nanostructures ICP_R may collimate the first light emitted from the first display device 10_R and convert a light path thereof. The plurality of first sub-nanostructures ICP_R may have a first sub-width, a first sub-height, and a first sub-spacing.

The plurality of second sub-nanostructures ICP_G may overlap the second display device 10_G in the second direction DR2. The plurality of second sub-nanostructures ICP_G may collimate the second light emitted from the second display device 10_G and convert a light path thereof. The plurality of second sub-nanostructures ICP_G may have a second sub-width, a second sub-height, and a second sub-spacing.

The plurality of third sub-nanostructures ICP_B may overlap the third display device 10_B in the second direction DR2. The plurality of third sub-nanostructures ICP_B may collimate the third light emitted from the third display device 10_B and convert a light path thereof. The plurality of third sub-nanostructures ICP_B may have a third sub-width, a third sub-height, and a third sub-spacing.

The first sub-nanostructure ICP_R, the second sub-nanostructure ICP_G, and the third sub-nanostructure ICP_B may be different from each other. In an embodiment, for example, the first sub-width, the second sub-width, and the third sub-width may be different from each other, or the first sub-height, the second sub-height, and the third sub-height may be different from each other, or the first sub-spacing, the second sub-spacing, and the third sub-spacing may be different from each other.

By each providing the first to third display devices 10_R, 10_G, and 10_B and the first to third sub-nanostructures ICP_R, ICP_G, and ICP_B for the first to third light, the embodiment may effectively prevent chromatic aberration in which light is focused at different locations depending on the color during the refraction process. Accordingly, in such an embodiment, the light of different colors may be focused on an accurate location, thereby providing the user with a clearer image.

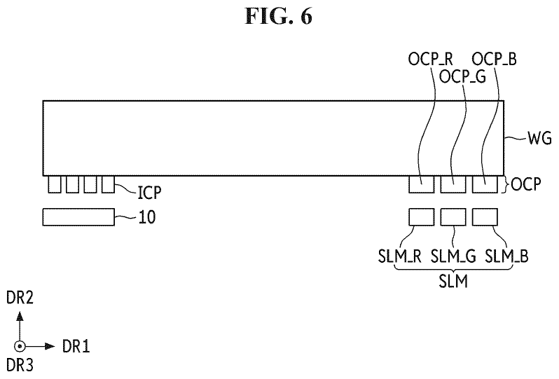

FIG. 6 is a plan view for describing the display device and the light guide portion of FIG. 1. Any repetitive detailed description of the same or like elements as those described above will be omitted or simplified, and the differences will be mainly described.

Referring to FIG. 6, the optical device according to some embodiments of the disclosure may include a first spatial light modulator SLM_R, a second spatial light modulator SLM_G, a third spatial light modulator SLM_B, a plurality of fourth sub-nanostructures OCP_R, a plurality of fifth sub-nanostructures OCP_G, and a plurality of sixth sub-nanostructures OCP_B.

In an embodiment, as shown in FIG. 2, the spatial light modulator SLM may be one spatial light modulator that modulates the phases of the first light, the second light, and the third light. In another embodiment, as shown in FIG. 6, the spatial light modulator SLM may include a first spatial light modulator SLM_R that modulates a phase of the first light, a second spatial light modulator SLM_G that modulates a phase of the second light, and a third spatial light modulator SLM_B that modulates a phase of the third light. The first spatial light modulator SLM_R, the second spatial light modulator SLM_G, and the third spatial light modulator SLM_B may each be an LCoS display device.

In an embodiment, as shown in FIG. 6, the plurality of second nanostructures OCP may include a plurality of fourth sub-nanostructures OCP_R, a plurality of fifth sub-nanostructures OCP_G, and a plurality of sixth sub-nanostructures OCP_B.

The plurality of fourth sub-nanostructures OCP_R may overlap the first spatial light modulator SLM_R in the second direction DR2. The plurality of fourth sub-nanostructures OCP_R may collimate the first light totally reflected by the light guide portion WG and convert a light path thereof to guide the reflected light to the first spatial light modulator SLM_R. The plurality of fourth sub-nanostructures OCP_R may have a fourth sub-width, a fourth sub-height, and a fourth sub-spacing.

The plurality of fifth sub-nanostructures OCP_G may overlap the second spatial light modulator SLM_G in the second direction DR2. The plurality of fifth sub-nanostructures OCP_G may collimate the second light totally reflected by the light guide portion WG and convert a light path thereof to guide the reflected light to the second spatial light modulator SLM_G. The plurality of fifth sub-nanostructures OCP_G may have a fifth sub-width, a fifth sub-height, and a fifth sub-spacing.

The plurality of sixth sub-nanostructures OCP_B may overlap the third spatial light modulator SLM_B in the second direction DR2. The plurality of sixth sub-nanostructures OCP_B may collimate the third light totally reflected by the light guide portion WG and convert a light path thereof to guide the reflected light to the third spatial light modulator SLM_B. The plurality of sixth sub-nanostructures OCP_B may have a sixth sub-width, a sixth sub-height, and a sixth sub-spacing.

The fourth sub-nanostructure OCP_R, the fifth sub-nanostructure OCP_G, and the sixth sub-nanostructure OCP_B may be different from each other. In an embodiment, for example, the fourth sub-width, the fifth sub-width, and the sixth sub-width may be different from each other, or the fourth sub-height, the fifth sub-height, and the sixth sub-height may be different from each other, or the fourth sub-spacing, the fifth sub-spacing, and the sixth sub-spacing may be different from each other.

By each providing the first to third spatial light modulators SLM_R, SLM_G, and SLM_B and the fourth to sixth sub-nanostructures OCP_R, OCP_G, and OCP_B for the first to third light, the embodiment may perform phase modulation of light by considering chromatic aberration in which the light is focused at different locations depending on the color during the refraction process. Accordingly, in such an embodiment, the light of different colors may be focused on an accurate location, thereby providing the user with a clearer image.

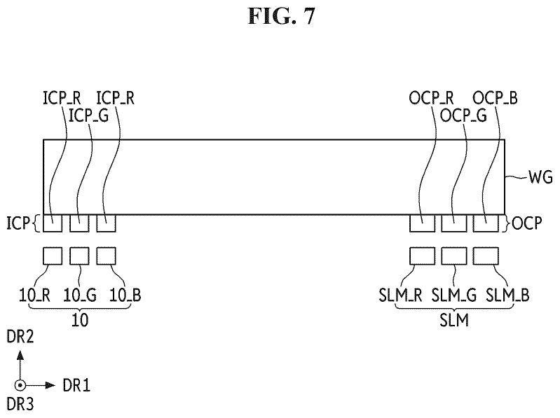

FIG. 7 is a plan view for describing the display device and the light guide portion of FIG. 1. Any repetitive detailed described of the same or like elements as those described above will be omitted or simplified, and the differences will be mainly described.

Referring to FIG. 7, the optical device according to some embodiments of the disclosure may include a first display device 10_R, a second display device 10_G, a third display device 10_B, a plurality of first sub-nanostructures ICP_R, a plurality of second sub-nanostructures ICP_G, a plurality of third sub-nanostructures ICP_B, a plurality of fourth sub-nanostructures OCP_R, a plurality of fifth sub-nanostructures OCP_G, a plurality of sixth sub-nanostructures OCP_B, a first spatial light modulator SLM_R, a second spatial light modulator SLM_G, and a third spatial light modulator SLM_B.

In an embodiment, as shown in FIG. 7, the spatial light modulator SLM may include a first spatial light modulator SLM_R that modulates a phase of the first light, a second spatial light modulator SLM_G that modulates a phase of the second light, and a third spatial light modulator SLM_B that modulates a phase of the third light. The first spatial light modulator SLM_R, the second spatial light modulator SLM_G, and the third spatial light modulator SLM_B may each be an LCoS display device.

In such an embodiment, the plurality of second nanostructures OCP may include a plurality of fourth sub-nanostructures OCP_R, a plurality of fifth sub-nanostructures OCP_G, and a plurality of sixth sub-nanostructures OCP_B.

The first to third spatial light modulators SLM_R, SLM_G, and SLM_B and the plurality of fourth to sixth sub-nanostructures OCP_R, OCP_G, and OCP_B of FIG. 7 may be substantially the same as the first to third spatial light modulators SLM_R, SLM_G, and SLM_B and the plurality of fourth to sixth sub-nanostructures OCP_R, OCP_G, and OCP_B described above with reference to FIGS. 5 and 6, respectively.

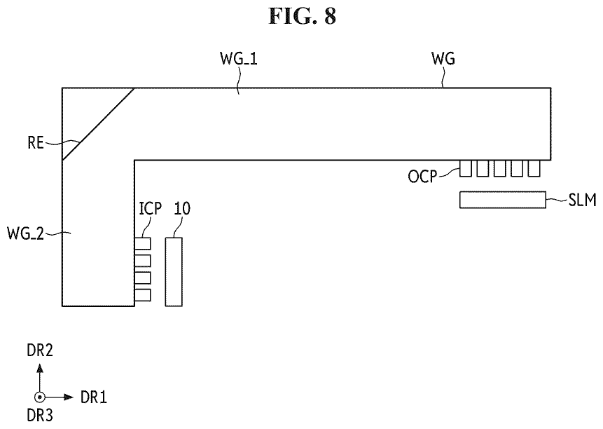

FIG. 8 is a plan view for describing the display device and the light guide portion of FIG. 1. Any repetitive detailed description of the same or like elements as those described above will be omitted or simplified, and the differences will be mainly described.

The display device 10, the plurality of first nanostructures ICP, the plurality of second nanostructures OCP, and the spatial light modulator SLM of FIG. 8 may be substantially the same as those described above with reference to FIG. 2.

Referring to FIG. 8, in an embodiment, the light guide portion WG may include a first extension portion WG_1 extending in the first direction DR1, a second extension portion WG_2 extending in the second direction DR2, and a reflector RE.

The first extension portion WG_1 may extend in the first direction DR1. A plurality of second nanostructures OCP may be located on one side of the first extension portion WG_1 in the first direction DR1. The spatial light modulator SLM may be arranged to be adjacent to the other side of the first extension portion WG_1. The plurality of second nanostructures OCP and the spatial light modulator SLM may overlap in the second direction DR2. The plurality of second nanostructures OCP and the spatial light modulator SLM may be arranged to be adjacent to each other in the second direction DR2.

The second extension portion WG_2 may extend in the second direction DR2. A plurality of first nanostructures ICP may be located on one side of the second extension portion WG_2 in an opposite direction to the second direction DR2. The display device 10 may be arranged to be adjacent to the one side of the second extension portion WG_2. The plurality of first nanostructures ICP and the display device 10 may overlap in the first direction DR1. The plurality of first nanostructures ICP and the display device 10 may be arranged to be adjacent to each other in the first direction DR1.

The reflector RE may be arranged in an area where the other side of the first extension portion WG_1 and the other side of the second extension portion WG_2 meet. The reflector RE may switch or change a traveling direction of light by reflecting the light traveling within the light guide portion WG. In an embodiment, for example, light directed in the second direction DR2 inside the light guide portion WG may be reflected through the reflector RE and travel in the first direction DR1.

In such an embodiment, as the light guide portion WG has the reflector RE, a length of the light guide portion WG in one direction may be reduced. Accordingly, miniaturization of the light guide portion WG becomes possible, thereby reducing the size of the optical device and improving the usability.

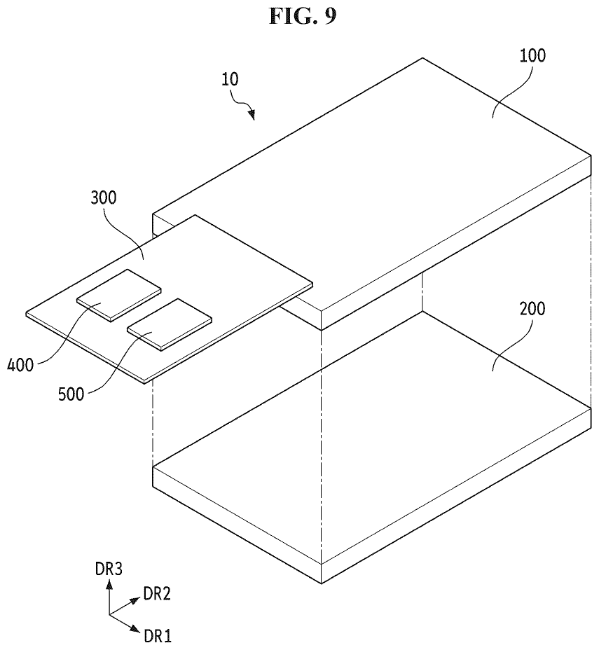

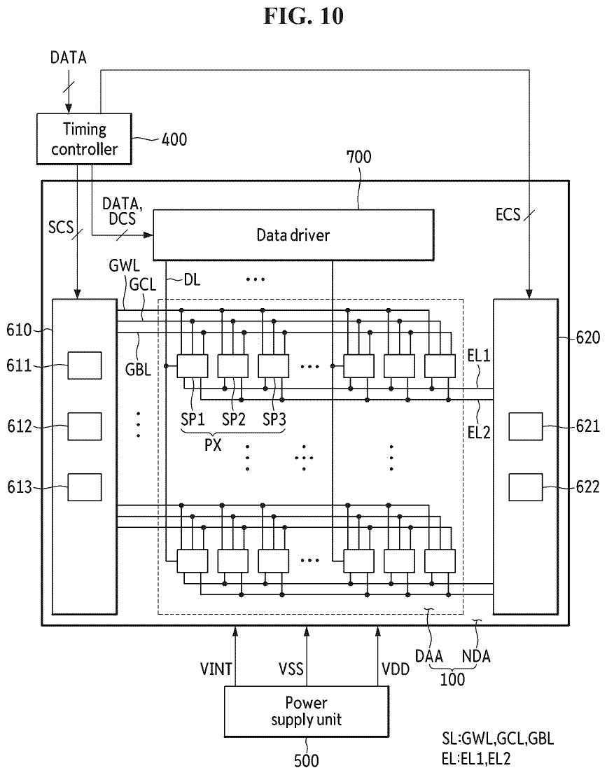

FIG. 9 is an exploded perspective view for describing the display device of FIG. 1. FIG. 10 is a block diagram for describing a display panel of FIG. 9.

Referring to FIGS. 9 and 10, the display device 10 according to an embodiment is a device that displays a moving image or a still image. The display device 10 according to an embodiment may be applied to portable electronic devices such as a mobile phone, a smart phone, a tablet personal computer (PC), a mobile communication terminal, an electronic notebook, an electronic book, a portable multimedia player (PMP), navigation, and an ultra mobile PC (UMPC). For example, the display device 10 according to an embodiment may be applied to a display unit of a television, a laptop computer, a monitor, a billboard, or the Internet of Things (IoT). Alternatively, the display device 10 according to an embodiment may be applied to a smart watch, a watch phone, and a head mounted display (HMD) for implementing virtual reality and augmented reality.

The display device 10 according to an embodiment includes a display panel 100, a heat dissipation layer 200, a circuit board 300, a timing control circuit 400, and a power supply circuit 500.

The display panel 100 may be formed in a planar shape similar to a quadrangle. In an embodiment, for example, the display panel 100 may have a planar shape similar to a quadrangle having short sides in a first direction DR1 and long sides in a second direction DR2 intersecting the first direction DR1. In the display panel 100, a corner where the short side in the first direction DR1 and the long side in the second direction DR2 meet may be rounded to have a predetermined curvature or may be formed at a right angle. The planar shape of the display panel 100 is not limited to the quadrangle, and may be formed similarly to other polygons, circles, or ovals. A planar shape of the display device 10 may correspond to the planar shape of the display panel 100, but the embodiment of the disclosure is not limited thereto.

The display panel 100 includes a plurality of pixels PX, a plurality of scan lines SL, a plurality of light-emitting control lines EL, a plurality of data lines DL, a scan driver 610, a light emitting driver 620, and a data driver 700. The display panel 100 may be divided into a display area DAA displaying an image and a non-display area NDA that does not display an image, as illustrated in FIG. 10.

The plurality of pixels PX may be arranged in the display area DAA. The plurality of pixels PX may be arranged in a matrix form in the first direction DR1 and the second direction DR2. The plurality of scan lines SL and the plurality of light-emitting control lines EL may extend in the first direction DR1 and may be arranged in the second direction DR2. The plurality of data lines DL may extend in the second direction DR2 and may be arranged in the first direction DR1.

The plurality of scan lines SL includes a plurality of write scan lines GWL, a plurality of control scan lines GCL, and a plurality of bias scan lines GBL. The plurality of light-emitting control lines EL include a plurality of first light-emitting control lines ECL1 and a plurality of second light-emitting control lines ECL2.

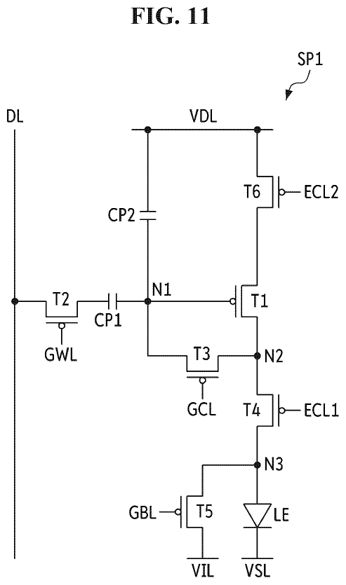

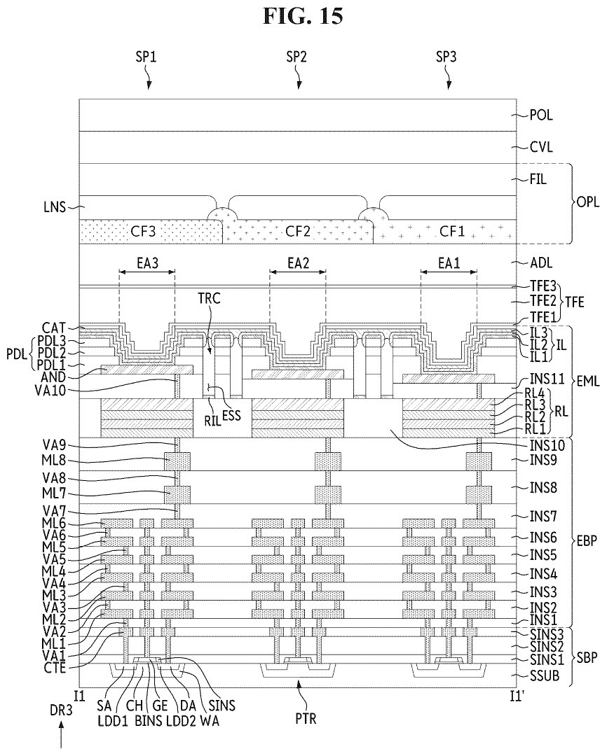

The plurality of pixels PX include a plurality of sub-pixels SP1, SP2, and SP3. In an embodiment, the plurality of sub-pixels SP1, SP2, and SP3 may include a plurality of pixel transistors as illustrated in FIG. 11, and the plurality of pixel transistors may be formed through a semiconductor process and may be located on a semiconductor substrate (SSUB in FIG. 15). In an embodiment, for example, the plurality of pixel transistors of the data driver 700 may include or be formed of a complementary metal oxide semiconductor (CMOS), but the embodiment of the disclosure is not limited thereto.

Each of the plurality of sub-pixels SP1, SP2, and SP3 may be connected to one write scan line GWL, one control scan line GCL, one bias scan line GBL, one first light-emitting control line ECL1, one second light-emitting control line ECL2, and one data line DL. Each of the plurality of sub-pixels SP1, SP2, and SP3 may receive a data voltage of the data line DL in response to a write scan signal of the write scan line GWL, and may emit light from a light emitting element corresponding to the data voltage.

The scan driver 610, the light emitting driver 620, and the data driver 700 may be arranged in the non-display area NDA.

The scan driver 610 includes a plurality of scan transistors, and the light emitting driver 620 includes a plurality of light emitting transistors. The plurality of scan transistors and the plurality of light emitting transistors may be formed through a semiconductor process and may be formed on a semiconductor substrate (SSUB in FIG. 15). In an embodiment, for example, the plurality of scan transistors and the plurality of light emitting transistors may include or be formed of CMOS, but the embodiment of the disclosure is not limited thereto.

The scan driver 610 may include a write scan signal output unit 611, a control scan signal output unit 612, and a bias scan signal output unit 613. Each of the write scan signal output unit 611, the control scan signal output unit 612, and the bias scan signal output unit 613 may receive a scan timing control signal SCS from the timing control circuit 400. The write scan signal output unit 611 may generate write scan signals based on the scan timing control signal SCS of the timing control circuit 400 and sequentially output the write scan signals to the write scan lines GWL. The control scan signal output unit 612 may generate control scan signals based on the scan timing control signal SCS and sequentially output the control scan signals to the control scan lines GCL. The bias scan signal output unit 613 may generate bias scan signals based on the scan timing control signal SCS and sequentially output the bias scan signals to the bias scan lines EBL.

The light emitting driver 620 includes a first light-emitting control driver 621 and a second light-emitting control driver 622. Each of the first light-emitting control driver 621 and the second light-emitting control driver 622 may receive a light-emitting timing control signal ECS from the timing control circuit 400. The first light-emitting control driver 621 may generate first light-emitting control signals according to the light-emitting timing control signal ECS and sequentially output the first light-emitting control signals to the first light-emitting control lines ECL1. The second light-emitting control driver 622 may generate second light-emitting control signals based on the light-emitting timing control signal ECS and sequentially output the second light-emitting control signals to the second light-emitting control lines ECL2.

The data driver 700 may include a plurality of data transistors, and the plurality of data transistors may be formed through a semiconductor process and may be formed on a semiconductor substrate (SSUB in FIG. 15). In an embodiment, for example, the plurality of data transistors may include or be formed of CMOS, but the embodiment of the disclosure is not limited thereto.

The data driver 700 may receive digital video data DATA and a data timing control signal DCS from the timing control circuit 400. The data driver 700 converts the digital video data DATA into analog data voltages according to the data timing control signal DCS and outputs the converted analog data voltages to the data lines DL. In such an embodiment, the sub-pixels SP1, SP2, and SP3 may be selected by the write scan signals of the scan driver 610, and the data voltages may be supplied to the selected sub-pixels SP1, SP2, and SP3.

The heat dissipation layer 200 may overlap the display panel 100 in the third direction DR3, which is a thickness direction of the display panel 100. The heat dissipation layer 200 may be located on one surface of the display panel 100, for example, a rear surface thereof. The heat dissipation layer 200 serves to dissipate heat generated from the display panel 100. The heat dissipation layer 200 may include a metal layer such as graphite, silver (Ag), copper (Cu), or aluminum (Al) having high thermal conductivity.

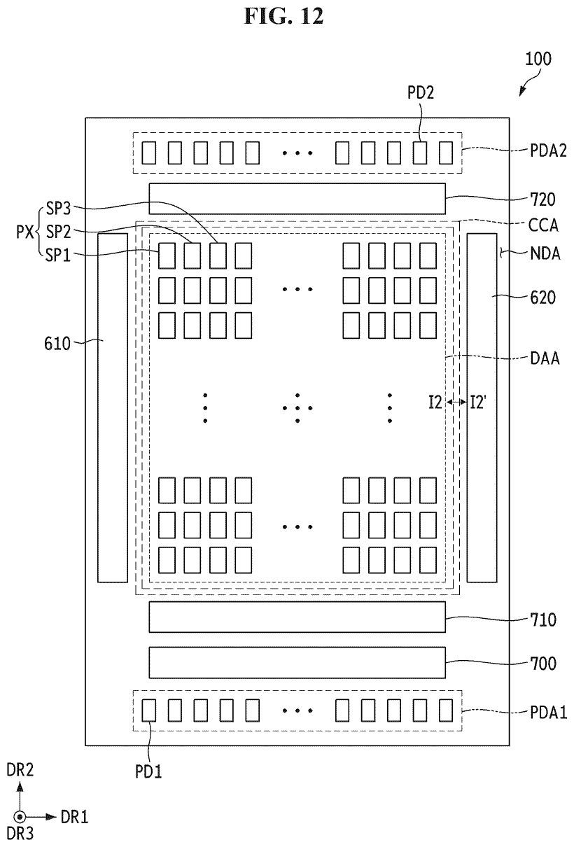

The circuit board 300 may be electrically connected to a plurality of first pads (PD1 in FIG. 12) of a first pad portion (PDA1 in FIG. 12) of the display panel 100 by using a conductive adhesive such as an anisotropic conductive film. The circuit board 300 may be a flexible printed circuit board or flexible film including or made of a flexible material. FIG. 9 illustrate an embodiment in a state where the circuit board 300 is unfolded, but the circuit board 300 may be bent. In a state where the circuit board 300 is bent, one end of the circuit board 300 may be located on the rear surface of the display panel 100 and/or a rear surface of the heat dissipation layer 200. The other end of the circuit board 300 may be connected to a plurality of first pads (PD1 in FIG. 12) of a first pad portion (PDA1 in FIG. 12) of the display panel 100 by using a conductive adhesive material. One end of the circuit board 300 may be an end opposite to the other end of the circuit board 300.

The timing control circuit 400 may receive digital video data and timing signals from the outside. The timing control circuit 400 may generate a scan timing control signal SCS, a light-emitting timing control signal ECS, and a data timing control signal DCS for controlling the display panel 100 according to the timing signals. The timing control circuit 400 may output the scan timing control signal SCS to the scan driver 610 and output the light-emitting timing control signal ECS to the light emitting driver 620. The timing control circuit 400 may output the digital video data and the data timing control signal DCS to the data driver 700.

The power supply circuit 500 may generate a plurality of panel driving voltages according to a power voltage from the outside. In an embodiment, for example, the power supply circuit 500 may generate a first driving voltage VSS, a second driving voltage VDD, and a third driving voltage VINT and supply the generated driving voltages to the display panel 100. The first driving voltage VSS, the second driving voltage VDD, and the third driving voltage VINT will be described later in greater detail with reference to FIG. 11.

Each of the timing control circuit 400 and the power supply circuit 500 may be formed as an integrated circuit (IC) and attached to one surface of the circuit board 300. In an embodiment, the scan timing control signal SCS, the light-emitting timing control signal ECS, the digital video data DATA, and the data timing control signal DCS of the timing control circuit 400 may be supplied to the display panel 100 through the circuit board 300. In addition, the first driving voltage VSS, the second driving voltage VDD, and the third driving voltage VINT of the power supply circuit 500 may be supplied to the display panel 100 through the circuit board 300.

Alternatively, each of the timing control circuit 400 and the power supply circuit 500 may be arranged in the non-display area NDA of the display panel 100, similarly to the scan driver 610, the light emitting driver 620, and the data driver 700. In such an embodiment, the timing control circuit 400 may include a plurality of timing transistors, and each of the power supply circuits 500 may include a plurality of power transistors. The plurality of timing transistors and the plurality of power transistors may be formed through a semiconductor process and may be formed on a semiconductor substrate (SSUB in FIG. 15). In an embodiment, for example, the plurality of timing transistors and the plurality of power transistors may include or be formed of CMOS, but the embodiment of the disclosure is not limited thereto. Each of the timing control circuit 400 and the power supply circuit 500 may be arranged between the data driver 700 and the first pad portion (PDA1 in FIG. 12).

FIG. 11 is an equivalent circuit diagram of a first sub-pixel of FIG. 10.

Referring to FIG. 11, in an embodiment, a first sub-pixel SP1 may be connected to the write scan line GWL, the control scan line GCL, the bias scan line EBL, the first light-emitting control line ECL1, the second light-emitting control line ECL2, and the data line DL. In addition, the first sub-pixel SP1 may be connected to a first driving voltage line VSL to which the first driving voltage VSS corresponding to a low potential voltage is applied, a second driving voltage line VDL to which the second driving voltage VDD corresponding to a high potential voltage is applied, and a third driving voltage line VIL to which the third driving voltage VINT corresponding to an initialization voltage is applied.

The first sub-pixel SP1 includes a plurality of transistors T1 to T6, a light emitting element LE, a first capacitor CP1, and a second capacitor CP2.

The light emitting element LE emits light according to a driving current Ids flowing through a channel of a first transistor T1. An amount of light emitted from the light emitting element LE may be proportional to the driving current (Ids). A first electrode of the light emitting element LE may be an anode electrode, and a second electrode of the light emitting element LE may be a cathode electrode. The light emitting element LE may be an organic light emitting diode including a first electrode, a second electrode, and an organic light emitting layer arranged between the first electrode and the second electrode, but the embodiment of the disclosure is not limited thereto. In an embodiment, for example, the light emitting element LE may be an inorganic light emitting element including a first electrode, a second electrode, and an inorganic semiconductor arranged between the first electrode and the second electrode. In such an embodiment, the light emitting element LE may be a micro light emitting diode.

The first transistor T1 may be a driving transistor that controls a source-drain current Ids (hereinafter, referred to as “driving current”) flowing between a source electrode and a drain electrode based on a voltage applied to a gate electrode.

A second transistor T2 may be arranged between one electrode of the first capacitor CP1 and the data line DL. The second transistor T2 is turned on by the write scan signal of the write scan line GWL and connects one electrode of the first capacitor CP1 to the data line DL. Accordingly, the data voltage of the data line DL may be applied to one electrode of the first capacitor CP1.

A third transistor T3 may be arranged between a first node N1 and a second node N2. The third transistor T3 is turned on by the write control signal of the write control line GCL and connects the first node N1 to the second node N2. Accordingly, when the gate electrode and the source electrode of the first transistor T1 are connected, the first transistor T1 may operate like a diode.

A fourth transistor T4 may be connected between the second node N2 and a third node N3. The fourth transistor T4 is turned on by the first light-emitting control signal of the first light-emitting control line ECL1 and connects the second node N2 to the third node N3. Accordingly, the driving current of the first transistor T1 may be supplied to the light emitting element LE. A fifth transistor T5 may be arranged between the third node N3 and the third driving voltage line VIL. The fifth transistor T5 is turned on by the bias scan signal of the bias scan line EBL and connects the third node N3 to the third driving voltage line VIL. Accordingly, the third driving voltage VINT of the third driving voltage line VIL may be applied to the first electrode of the light emitting element LE.

A sixth transistor T6 may be arranged between the source electrode of the first transistor T1 and the second driving voltage line VDL. The sixth transistor T6 is turned on by the second light-emitting control signal of the second light-emitting control line ECL2 and connects the source electrode of the first transistor T1 to the second driving voltage line VDL. Accordingly, the second driving voltage VDD of the second driving voltage line VDL may be applied to the source electrode of the first transistor T1.

The first capacitor CP1 is formed or connected between the first node N1 and the drain electrode of the second transistor T2. The second capacitor CP2 is formed or connected between the gate electrode of the first transistor T1 and the second driving voltage line VDL.

Each of the first to sixth transistors T1 to T6 may be a metal-oxide-semiconductor field effect transistor (MOSFET). In an embodiment, for example, each of the first to sixth transistors T1 to T6 may be a p-type MOSFET, but the embodiment of the disclosure is not limited thereto. Each of the first to sixth transistors T1 to T6 may be an n-type MOSFET. Alternatively, each of some of the first to sixth transistors T1 to T6 may be a p-type MOSFET, and each of the remaining transistors may be an n-type MOSFET.

FIG. 11 illustrates an embodiment where the first sub-pixel SP1 includes six transistors T1 to T6 and two capacitors CP1 and CP2, but it should be noted that the equivalent circuit diagram of the first sub-pixel SP1 is not limited to that illustrated in FIG. 11. For example, the number of transistors and capacitors of the first sub-pixel SP1 is not limited to that illustrated in FIG. 11.

In addition, an equivalent circuit diagram of a second sub-pixel SP2 and an equivalent circuit diagram of a third sub-pixel SP3 may be substantially the same as the equivalent circuit diagram of the first sub-pixel SP1 described with reference to FIG. 3. Therefore, any repetitive detailed descriptions of the equivalent circuit diagram of the second sub-pixel SP2 and the equivalent circuit diagram of the third sub-pixel SP3 are omitted in the disclosure.

FIG. 12 is a plan view for describing the display panel of FIG. 9.

Referring to FIG. 12, the display area DAA of the display panel 100 according to an embodiment includes a plurality of pixels PX arranged in a matrix form. The non-display area NDA of the display panel 100 according to an embodiment includes a scan driver 610, a light emitting driver 620, a data driver 700, a first distribution circuit 710, a second distribution circuit 720, a first pad portion PDA1, and a second pad portion PDA2.

The scan driver 610 may be located on a first side of the display area DAA, and the light emitting driver 620 may be located on a second side of the display area DAA. In an embodiment, for example, the scan driver 610 may be located on one side of the display area DAA in the first direction DR1, and the light emitting driver 620 may be located on the other side of the display area DAA in the first direction DR1. However, the embodiment of the disclosure is not limited thereto, and the scan driver 610 and the light emitting driver 620 may be located on both the first side and the second side of the display area DAA.

The first pad portion PDA1 may include a plurality of first pads PD1 connected to pads or bumps of the circuit board 300 through a conductive adhesive. The first pad portion PDA1 may be located on a third side of the display area DAA. In an embodiment, for example, the first pad portion PDA1 may be located on one side of the display area DAA in the second direction DR2. The first pad portion PDA1 may be located on the outside of the data driver 700 in the second direction DR2.

The second pad portion PDA2 may include a plurality of second pads PD2 corresponding to test pads for testing whether the display panel 100 is normally operating. The plurality of second pads PD2 may be connected to a jig or probe pin or to a test circuit board during the test process. The test circuit board may be a printed circuit board including or made of a rigid material or a flexible printed circuit board including or made of a flexible material.

The second pad portion PDA2 may be located on a fourth side of the display area DAA. In an embodiment, for example, the second pad portion PDA2 may be located on the other side of the display area DAA in the second direction DR2. The second pad portion PDA2 may be located on the outside of the second distribution circuit 720 in the second direction DR2.

The first distribution circuit 710 distributes data voltages applied through the first pad portion PDA1 to the plurality of data lines DL. In an embodiment, for example, the first distribution circuit 710 may distribute data voltages applied through one first pad PD1 of the first pad portion PDA1 to P (P is a positive integer greater than or equal to 2) data lines DL, thereby reducing the number of first pads PD1. The first distribution circuit 710 may be located on a third side of the display area DAA of the display panel 100. In an embodiment, for example, the first distribution circuit 710 may be located on one side of the display area DAA in the second direction DR2.

The second distribution circuit 720 distributes signals applied through the second pad portion PDA2 to the scan driver 610, the light emitting driver 620, and the data lines DL. The second pad portion PDA2 and the second distribution circuit 720 may be components for testing the operation of each pixel PX of the display area DAA. The second distribution circuit 720 may be located on a fourth side of the display area DAA of the display panel 100. In an embodiment, for example, the second distribution circuit 720 may be located on the other side of the display area DAA in the second direction DR2.

A cathode connection portion CCA may be an area where a second electrode (CAT in FIG. 15) of a display element layer (EML in FIG. 15) is connected to the first driving voltage line VSL of the non-display area NDA. The cathode connection portion CCA may be arranged outside at least one side of the display area DAA. In an embodiment, for example, the cathode connection portion CCA may be arranged outside at least one selected from the left, right, upper, and lower sides of the display area DA. Alternatively, the cathode connection portion CCA may be arranged to surround the display area DA as illustrated in FIG. 12 to minimize a deviation in the first driving voltage VSS due to a voltage drop (IR drop) or voltage rising (IR rise) of the second electrode CAT in the display area DA.

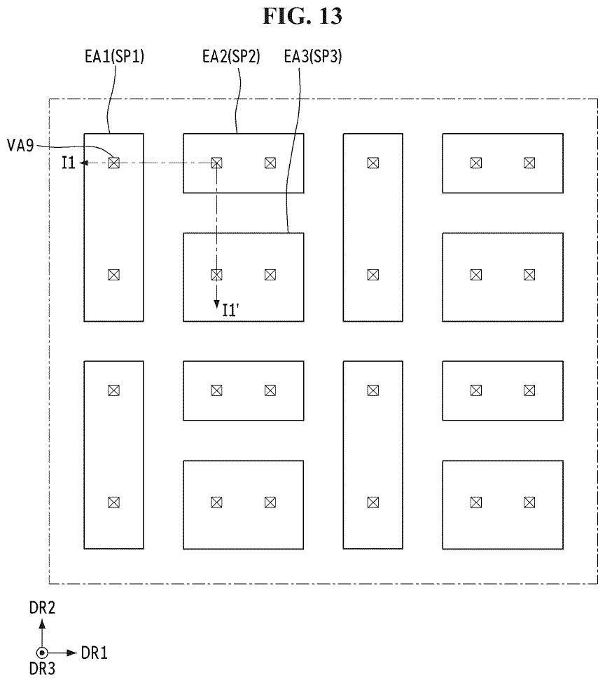

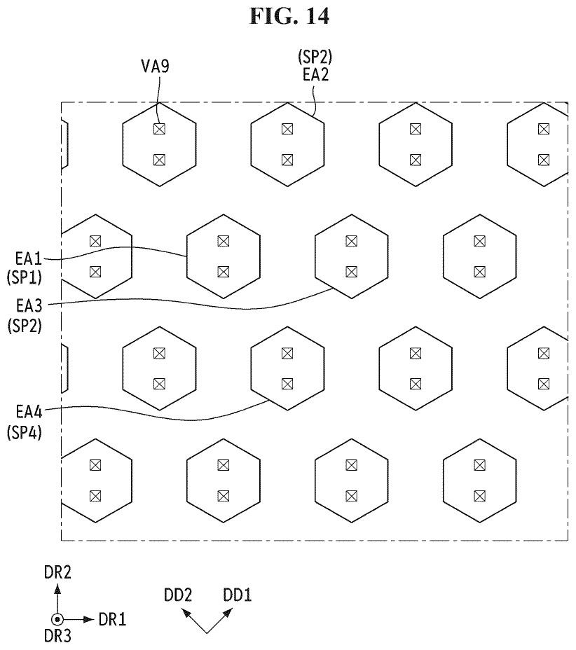

FIG. 13 is a plan view for describing the display area of FIG. 12. FIG. 14 is a plan view for describing the display area of FIG. 12.

Referring to FIGS. 13 and 14, each of the plurality of pixels PX includes a first light emitting area EA1, which is a light emitting area of the first sub-pixel SP1, a second light emitting area EA2, which is a light emitting area of the second sub-pixel SP2, and a third light emitting area EA3, which is a light emitting area of the third sub-pixel SP3.

The first light emitting area EA1, the second light emitting area EA2, and the third light emitting area EA3 may have a quadrangular or hexagonal planar shape as illustrated in FIGS. 13 and 14, but the embodiment of the disclosure is not limited thereto. The first light emitting area EA1, the second light emitting area EA2, and the third light emitting area EA3 have a planar shape other than the quadrangle or hexagon, such as a polygon, circle, ellipse, or irregular shape.

In an embodiment, as illustrated in FIG. 13, in each of the plurality of pixels PX, the first light emitting area EA1 and the second light emitting area EA2 may be adjacent to each other in the first direction DR1. In addition, the first light emitting area EA1 and the third light emitting area EA3 may be adjacent to each other in the first direction DR1. In addition, the second light emitting area EA2 and the third light emitting area EA3 may be adjacent to each other in the second direction DR2. An area of the first light emitting area EA1, an area of the second light emitting area EA2, and an area of the third light emitting area EA3 may be different.

Alternatively, as illustrated in FIG. 14, the light emitting areas EA1, EA2, EA3, and EA4 may have a hexagonal planar shape. In such an embodiment, the first light emitting area EA1 and the third light emitting area EA3 may be adjacent to each other in the first direction DR1, and the second light emitting area EA2 and a fourth light emitting area EA4 may be adjacent to each other in the second direction DR2. In addition, the first light emitting area EA1 and the second light emitting area EA2 may be adjacent to each other in a first diagonal direction DD1, and the second light emitting area EA2 and the third light emitting area EA3 may be adjacent to each other in a second diagonal direction DD2. In addition, the first light emitting area EA1 and the fourth light emitting area EA4 may be adjacent to each other in the second diagonal direction DD2, and the third light emitting area EA3 and the fourth light emitting area EA4 may be adjacent to each other in the first diagonal direction DD1. The first diagonal direction DD1, which is a direction between the first direction DR1 and the second direction DR2, may indicate a direction inclined by about 45 degrees compared to the first direction DR1 and the second direction DR2, and the second diagonal direction DD2 may be a direction perpendicular to the first diagonal direction DD1.

The first sub-pixel SP1 may emit first light, the second sub-pixel SP2 may emit second light, and the third sub-pixel SP3 may emit third light. Here, the first light may be light of a blue wavelength band, the second light may be light of a green wavelength band, and the third light may be light of a red wavelength band. In an embodiment, for example, the blue wavelength band may indicate that a main peak wavelength of light is included in a wavelength band of about 370 nm to about 460 nm, the green wavelength band may indicate that a main peak wavelength of light is included in a wavelength band of about 480 nm to about 560 nm, and the red wavelength band may indicate that a main peak wavelength of light is included in a wavelength band of about 600 nm to about 750 nm.

Each of the plurality of pixels PX may include three light emitting areas EA1, EA2, and EA3 as illustrated in FIG. 13 or may include four light emitting areas EA1, EA2, EA3, and EA4 as illustrated in FIG. 14. In such an embodiment, a fourth light emitting area EA4 may emit the same second light as the second light emitting area EA2, but the embodiment of the disclosure is not limited thereto.

The light emitting areas of the plurality of pixels PX may be arranged in a stripe structure, in which the light-emitting areas are arranged in the first direction DR1, a PenTile® structure, in which the light emitting areas EA1, EA2, EA3, and EA4 are arranged in a rhombus shape as illustrated in FIG. 14, or a hexagonal structure in which the light emitting regions are arranged in a hexagonal shape.

FIG. 15 is a cross-sectional view taken along line I1-I1′ of FIG. 13, showing an embodiment of the display panel.

Referring to FIG. 15, an embodiment of the display panel 100 includes a semiconductor backplane SBP, a light emitting element backplane EBP, a display element layer EML, an encapsulation layer TFE, an optical layer OPL, a cover layer CVL, and a polarizing plate POL.

The semiconductor backplane SBP includes a semiconductor substrate SSUB including a plurality of pixel transistors PTR, a plurality of semiconductor insulating films covering the plurality of pixel transistors PTR, and a plurality of contact terminals CTE electrically connected to the plurality of pixel transistors PTR, respectively. The plurality of pixel transistors PTR may be the first to sixth transistors T1 to T6 described with reference to FIG. 11.

The semiconductor substrate SSUB may be a silicon substrate, a germanium substrate, or a silicon-germanium substrate. The semiconductor substrate SSUB may be a substrate doped with first-type impurities. A plurality of well areas WA may be located on an upper surface of the semiconductor substrate SSUB. The plurality of well areas WA may be areas doped with second-type impurities. The second-type impurity may be different from the first-type impurity described above. In an embodiment, for example, where the first-type impurity is a p-type impurity, the second-type impurity may be an n-type impurity. In another embodiment, where the first-type impurity is an n-type impurity, the second-type impurity may be a p-type impurity.

Each of the plurality of well areas WA includes a source area SA corresponding to a source electrode of the pixel transistor PTR, a drain area DA corresponding to a drain electrode thereof, and a channel area CH arranged between the source area SA and the drain area DA.

A lower insulating film BINS may be arranged between the gate electrode GE and the well area WA. A side insulating film SINS may be located on a side surface of the gate electrode GE. The side insulating film SINS may be located on the lower insulating film BINS.

Each of the source area SA and the drain area DA may be an area doped with first-type impurities. A gate electrode GE of the pixel transistor PTR may overlap the well area WA in the third direction DR3, which is a thickness direction of the semiconductor substrate SSUB. The channel area CH may overlap the gate electrode GE in the third direction DR3. The source area SA may be located on one side of the gate electrode GE, and the drain area DA may be located on the other side of the gate electrode GE.

Each of the plurality of well areas WA further includes a first low-concentration impurity area LDD1 arranged between the channel area CH and the source area SA and a second low-concentration impurity area LDD2 arranged between the channel area CH and the drain area DA. The first low-concentration impurity area LDD1 may be an area having an impurity concentration lower than that of the source area SA due to the lower insulating film BINS. The second low-concentration impurity area LDD2 may be an area having an impurity concentration lower than that of the drain area DA due to the lower insulating film BINS. A distance between the source area SA and the drain area DA may be increased by the first low-concentration impurity area LDD1 and the second low-concentration impurity area LDD2, which may increase a length of the channel area CH of each pixel transistor PTR.

A first semiconductor insulating film SINS1 may be located on the semiconductor substrate SSUB. A semiconductor insulating film SINS2 may be located on the first semiconductor insulating film SINS1.

A plurality of contact terminals CTE may be located on the second semiconductor insulating film SINS2. Each of the plurality of contact terminals CTE may be connected to at least one selected from the gate electrode GE, the source area SA, and the drain area DA of each of the plurality of pixel transistors PTR through a hole defined or formed through the first semiconductor insulating film SINS1 and the second semiconductor insulating film SINS2. The plurality of contact terminals CTE may include or be formed of at least one selected from copper (Cu), aluminum (Al), tungsten (W), molybdenum (Mo), chromium (Cr), gold (Au), titanium (Ti), nickel (Ni), and neodymium (Nd), or an alloy including any one thereof.

A third semiconductor insulating film SINS3 may be located on a side surface of each of the plurality of contact terminals CTE. An upper surface of each of the plurality of contact terminals CTE may be exposed without being covered by the third semiconductor insulating film SINS3.

Each of the first semiconductor insulating film SINS1, the second semiconductor insulating film SINS2, and the third semiconductor insulating film SINS3 may include or be formed of an inorganic film including silicon nitride carbon (SiCN) or silicon oxide (SiOx), but the embodiment of the disclosure is not limited thereto.

The semiconductor substrate SSUB may be replaced with a glass substrate or a polymer resin substrate such as polyimide. In an embodiment, thin film transistors may be located on the glass substrate or the polymer resin substrate. The glass substrate may be a rigid substrate that is not bent, and the polymer resin substrate may be a flexible substrate that may be bent or curved.

The light emitting element backplane EBP includes a plurality of conductive layers ML1 to ML8, a plurality of vias VA1 to VA9, and a plurality of insulating films INS1 to INS11. In addition, the light emitting element backplane EBP includes a plurality of insulating films INS1 to INS9 arranged between the first to eighth conductive layers ML1 to ML8.

The first to eighth insulating films INS1 to INS8 serve to insulate the first to eighth conductive layers ML1 to ML8. The first to eighth conductive layers ML1 to ML8 serve to implement the circuit of the first sub-pixel SP1 illustrated in FIG. 12 by connecting the plurality of contact terminals CTE exposed from the semiconductor backplane SBP.

In an embodiment, for example, only the first to sixth transistors T1 to T6 are formed on the semiconductor backplane SBP, and the first to sixth transistors T1 to T6 and the first and second capacitors C1 and C2 are connected through the first to eighth conductive layers ML1 to ML8. In addition, the drain area corresponding to the drain electrode of the fourth transistor T4, the source area corresponding to the source electrode of the fifth transistor T5, and the first electrode AND of the light emitting element LE are also connected through the first to eighth conductive layers ML1 to ML8.

The first to eighth conductive layers ML1 to ML8 and the first to eighth vias VA1 to VA8 may include or be formed of substantially a same material as each other. The first to eighth conductive layers ML1 to ML8 and the first to eighth vias VA1 to VA8 may include or be formed of at least one selected from copper (Cu), aluminum (Al), tungsten (W), molybdenum (Mo), chromium (Cr), gold (Au), titanium (Ti), nickel (Ni), and neodymium (Nd), or an alloy including any one thereof. The first to eighth vias VA1 to VA8 may include or be formed of substantially a same material as each other. The first to eighth insulating films INS1 to INS8 may include or be formed of an inorganic film including silicon oxide (SiOₓ), but the embodiment of the disclosure is not limited thereto.

A ninth insulating film INS9 may be located on the eighth insulating film INS8 and the eighth conductive layer ML8. The ninth insulating film INS9 may include or be formed of an inorganic film including silicon oxide (SiOₓ), but the embodiment of the disclosure is not limited thereto.

Each of the ninth vias VA9 may be connected to the eighth conductive layer ML8 exposed by penetrating through the ninth insulating film INS9. The ninth vias VA9 may include or be formed of at least one selected from copper (Cu), aluminum (Al), tungsten (W), molybdenum (Mo), chromium (Cr), gold (Au), titanium (Ti), nickel (Ni), and neodymium (Nd), or an alloy including any one thereof.

The display element layer EML may be located on the light emitting element backplane EBP. The display element layer EML may include tenth and eleventh insulating films INS10 and INS11, a reflective electrode layer RL, first electrodes AND, a light emitting stack IL, a second electrode CAT, a pixel defining film PDL, and a plurality of trenches TRC.

The reflective electrode layer RL may be located on the ninth insulating film INS9. The reflective electrode layer RL may include at least one or more reflective electrodes RL1, RL2, RL3, and RL4. In an embodiment, for example, the reflective electrode layer RL may include first to fourth reflective electrodes RL1, RL2, RL3, and RL4 as illustrated in FIG. 15.

The first reflective electrodes RL1 may be located on the ninth insulating film INS9 and may be connected to the ninth via VA9. Each of second reflective electrodes RL2 may be located on the first reflective electrode RL1 corresponding thereto. Each of third reflective electrodes RL3 may be located on the second reflective electrode RL2 corresponding thereto. Each of fourth reflective electrodes RL4 may be located on the third reflective electrode RL3 corresponding thereto.

Since the second reflective electrode RL2 may be an electrode that substantially reflects light from the light emitting elements, a thickness of the second reflective electrode RL2 may be greater than a thickness of the first reflective electrode RL1, a thickness of the third reflective electrode RL3, and a thickness of the fourth reflective electrode RL4.

The first reflective electrodes RL1 may include or be formed of at least one selected from copper (Cu), aluminum (Al), tungsten (W), molybdenum (Mo), chromium (Cr), gold (Au), titanium (Ti), nickel (Ni), and neodymium (Nd), or an alloy including any one thereof. In an embodiment, for example, the first reflective electrodes RL1 may include titanium nitride (TiN), the second reflective electrodes RL2 may include aluminum (Al), the third reflective electrodes RL3 may include titanium nitride (TiN), and the fourth reflective electrodes RL4 may include titanium (Ti).

A tenth interlayer insulating film INS10 may be located on the ninth interlayer insulating film INS9. The tenth interlayer insulating film INS10 may be arranged between the reflective electrodes RL adjacent to each other. The tenth interlayer insulating film INS10 may be a film for planarizing a level difference caused by the reflective electrodes RL. The eleventh interlayer insulating film INS11 may be located on the tenth interlayer insulating film INS10 and the reflective electrode RL.

The tenth interlayer insulating film INS10 and the eleventh interlayer insulating film INS11 may include or be formed of an inorganic film including silicon oxide (SiOx), but the embodiment of the disclosure is not limited thereto.

The eleventh interlayer insulating film INS11 may be an optical auxiliary layer for adjusting a resonance distance of light emitted from the light emitting stack IL in at least one sub-pixel of the first sub-pixel SP1, the second sub-pixel SP2, and the third sub-pixel SP3. A thickness of the eleventh interlayer insulating film INS11 in the first sub-pixel SP1, the second sub-pixel SP2, and the third sub-pixel SP3 may be different. That is, in order to adjust a distance from the reflective electrode RL to the second electrode CAT according to a main wavelength of light emitted from each of the first sub-pixel SP1, the second sub-pixel SP2, and the third sub-pixel SP3, the thickness of the eleventh interlayer insulating film INS11 may be set in each of the first sub-pixel SP1, the second sub-pixel SP2, and the third sub-pixel SP3.

In an embodiment, for example, as illustrated in FIG. 15, the thickness of the eleventh interlayer insulating film INS11 in the first sub-pixel SP1 may be greater than the thickness of the eleventh interlayer insulating film INS11 in the second sub-pixel SP2, and the thickness of the eleventh interlayer insulating film INS11 in the second sub-pixel SP2 may be greater than the thickness of the eleventh interlayer insulating film INS11 in the third sub-pixel SP3. In this case, a distance between the first electrode AND and the reflective electrode RL in the first sub-pixel SP1 may be greater than a distance between the first electrode AND and the reflective electrode RL in the second sub-pixel SP2. In addition, the distance between the first electrode AND and the reflective electrode RL in the second sub-pixel SP2 may be greater than a distance between the first electrode AND and the reflective electrode RL in the third sub-pixel SP3.

Each of the tenth vias VA10 may be connected to the ninth metal layer ML9 exposed by penetrating through the eleventh interlayer insulating film INS11. The tenth vias VA10 may include or be formed of at least one selected from copper (Cu), aluminum (Al), tungsten (W), molybdenum (Mo), chromium (Cr), gold (Au), titanium (Ti), nickel (Ni), and neodymium (Nd), or an alloy including any one thereof. A thickness of the tenth via VA10 in the first sub-pixel SP1 may be greater than a thickness of the tenth via VA10 in the second sub-pixel SP2, and the thickness of the tenth via VA10 in the second sub-pixel SP2 may be greater than a thickness of the tenth via VA10 in the third sub-pixel SP3.

The first electrode AND of each of the light emitting elements LE may be located on the eleventh interlayer insulating film INS11 and may be connected to the tenth via VA10. The first electrode AND of each of the light emitting elements LE may be connected to the drain area DA or the source area SA of the pixel transistor PTR through the tenth via VA10, the reflective electrode RL, the first to ninth vias VA1 to VA9, the first to eighth conductive layers ML1 to ML8, and the contact terminal CTE. The first electrode AND of each of the light emitting elements LE may include or be formed of at least one selected from copper (Cu), aluminum (Al), tungsten (W), molybdenum (Mo), chromium (Cr), gold (Au), titanium (Ti), nickel (Ni), and neodymium (Nd), or an alloy including any one thereof. In an embodiment, for example, the first electrode AND of each of the light emitting elements LE may include or be formed of titanium nitride (TiN).

The pixel defining film PDL may be located on a partial area of the first electrode AND of each of the light emitting elements LE. The pixel defining film PDL may cover an edge of the first electrode AND of each of the light emitting elements LE. The pixel defining film PDL may partition the first light emitting areas EA1, the second light emitting areas EA2, and the third light emitting areas EA3. Each of the first light emitting area EA1, the second light emitting area EA2, and the third light emitting area EA3 may be an area in which the light emitting element LE including the first electrode AND, the light emitting stack IL, and the second electrode CAT is arranged.

The first light emitting area EA1 may be defined as an area in which the first electrode AND, the light emitting stack IL, and the second electrode CAT are sequentially stacked in the first sub-pixel SP1 to emit light. The second light emitting area EA2 may be defined as an area in which the first electrode AND, the light emitting stack IL, and the second electrode CAT are sequentially stacked in the second sub-pixel SP2 to emit light. The third light emitting area EA3 may be defined as an area in which the first electrode AND, the light emitting stack IL, and the second electrode CAT are sequentially stacked in the third sub-pixel SP3 to emit light.

The pixel defining film PDL may include first to third pixel defining films PDL1, PDL2, and PDL3. The first pixel defining film PDL1 may be located on the edge of the first electrode AND of each of the light emitting elements LE, the second pixel defining film PDL2 may be located on the first pixel defining film PDL1, and the third pixel defining film PDL3 may be located on the second pixel defining film PDL2. The first pixel defining film PDL1, the second pixel defining film PDL2, and the third pixel defining film PDL3 may include or be formed of an inorganic film including silicon oxide (SiOₓ). Alternatively, the first pixel defining film PDL1 and the third pixel defining film PDL3 include or are formed of an inorganic film of silicon nitride (SiNₓ) series, while the second pixel defining film PDL2 may include or be formed of an inorganic film including silicon oxide (SiOₓ). Each of a thickness of the first pixel defining film PDL1, a thickness of the second pixel defining film PDL2, and a thickness of the third pixel defining film PDL3 may be about 500 angstrom (Å).

In an embodiment, the first pixel defining film PDL1, the second pixel defining film PDL2, and the third pixel defining film PDL3 may have a cross-sectional structure with a step-shaped level difference to prevent the first encapsulation inorganic film TFE1 from being disconnected due to the step coverage. The step coverage refers to a ratio of the extent to which a thin film is applied to an inclined portion relative to the extent to which a thin film is applied to a flat portion. As the step coverage is low, the possibility of the thin film disconnected at the inclined portion may increase.

Each of the plurality of trenches TRC may penetrate through the first pixel defining film PDL1, the second pixel defining film PDL2, and the third pixel defining film PDL3. In each of the plurality of trenches TRC, at least a portion of the eleventh interlayer insulating film INS11 may have a recessed shape.

At least one trench TRC may be arranged between the sub-pixels SP1, SP2, and SP3 adjacent to each other. In an embodiment, as shown in FIG. 15, two trenches TRC are arranged between the sub-pixels SP1, SP2, and SP3 adjacent to each other, but the embodiment of the disclosure is not limited thereto.

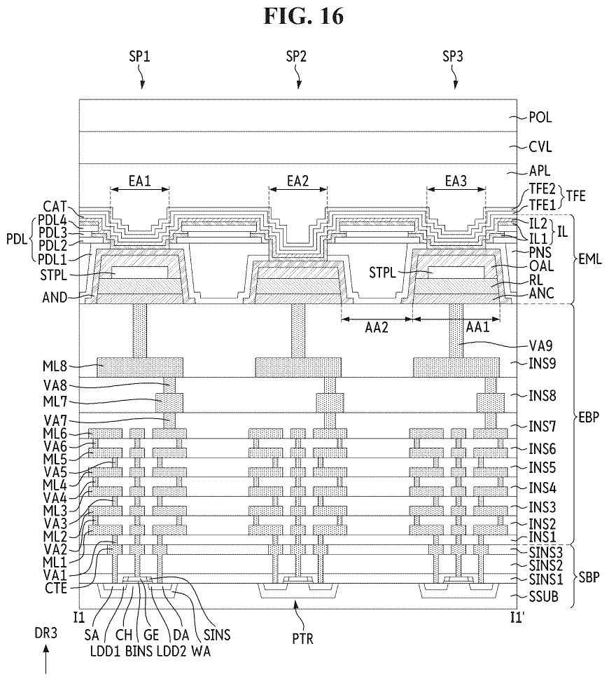

The light emitting stack IL may include a plurality of stack layers IL1, IL2, and IL3. in an embodiment, as shown in FIG. 15, the light emitting stack IL has a three-tandem structure including a first stack layer IL1, a second stack layer IL2, and a third stack layer IL3, but the embodiment of disclosure is not limited thereto. In an embodiment, for example, the light emitting stack IL may have a two-tandem structure including two stack layers as illustrated in FIG. 16.

In an embodiment where the light emitting stack IL has the three-tandem structure, the light emitting stack IL may have a tandem structure including a plurality of stack layers IL1, IL2, and IL3 that emit different lights. In an embodiment, for example, the light emitting stack IL may include a first stack layer IL1 that emits light of a first color, a second stack layer IL2 that emits light of a second color, and a third stack layer IL3 that emits light of a third color. The first stack layer IL1, the second stack layer IL2, and the third stack layer IL3 may be sequentially stacked.

The first stack layer IL1 may have a structure in which a first hole transporting layer, a first light emitting layer emitting first light, and a first electron transporting layer are sequentially stacked. The second stack layer IL2 may have a structure in which a second hole transporting layer, a second light emitting layer emitting second light, and a second electron transporting layer are sequentially stacked. The third stack layer IL3 may have a structure in which a third hole transporting layer, a third organic light emitting layer emitting third light, and a third electron transporting layer are sequentially stacked.

A first charge generation layer for supplying charges to the second stack layer IL2 and supplying electrons to the first stack layer IL1 may be arranged between the first stack layer IL1 and the second stack layer IL2. The first charge generation layer may include an n-type charge generation layer that supplies electrons to the first stack layer IL1 and a p-type charge generation layer that supplies holes to the second stack layer IL2. The n-type charge generation layer may include a dopant of a metallic material.

A second charge generation layer for supplying charges to the third stack layer IL3 and supplying electrons to the second stack layer IL2 may be arranged between the second stack layer IL2 and the third stack layer IL3. The second charge generation layer may include an n-type charge generation layer that supplies electrons to the second stack layer IL2 and a p-type charge generation layer that supplies holes to the third stack layer IL3.

The first stack layer IL1 may be located on the first electrodes AND and the pixel defining film PDL, and in each of the trenches TRC, a residual film RIL located on a bottom surface of the trench TRC may be the same material as the first stack layer IL1. Due to the trench TRC, the first stack layer IL1 may be disconnected between the sub-pixels SP1, SP2, and SP3 adjacent to each other. The second stack layer IL2 may be located on the first stack layer IL1. Due to the trench TRC, the second stack layer IL2 may be disconnected between the sub-pixels SP1, SP2, and SP3 adjacent to each other. A cavity ESS or empty space may be arranged between the residual film RIL and the second stack layer IL2 in the trench TRC. The third stack layer IL3 may be located on the second stack layer IL2. The third stack layer IL3 may not be disconnected by the trench TRC and may be arranged to cover the second stack layer IL2 in each of the trenches TRC.

In an embodiment where the light emitting stack IL has the three-tandem structure, each of the plurality of trenches TRC may be a structure for disconnecting the first to third hole transporting layers, the first charge generation layer, and the second charge generation layer of the first to third stack layers IL1, IL2, and IL3 of the display element layer EML between the sub-pixels SP1, SP2, and SP3 adjacent to each other. In addition, in the two-tandem structure, each of the plurality of trenches TRC may be a structure for disconnecting the charge generation layer arranged between a lower stack layer and an upper stack layer and the lower stack layer.

In an embodiment, a height of each of the plurality of trenches TRC may be greater than a height of the pixel defining film PDL to stably disconnect the first and second stack layers IL1 and IL2 of the display element layer EML between the sub-pixels SP1, SP2, and SP3 adjacent to each other. The height of each of the plurality of trenches TRC indicates a length of each of the plurality of trenches TRC in the third direction DR3. The height of the pixel defining film PDL indicates a length of the pixel defining film PDL in the third direction DR3. In an embodiment, other structures may be present instead of the trench TRC to disconnect the hole transporting layers and the charge generation layers of the light emitting stack IL of the display element layer EML between the sub-pixels SP1, SP2, and SP3 adjacent to each other. In an embodiment, for example, instead of the trench TRC, a partition wall having a reverse tapered shape may be located on the pixel defining film PDL.

In an embodiment, as shown in FIG. 15, the light emitting stack IL that emits light is arranged in all of the first light emitting area EA1, the second light emitting area EA2, and the third light emitting area EA3, but the embodiment of the disclosure is not limited thereto. In an embodiment, for example, instead of the light emitting stack IL, the first light emitting stack IL1 may be arranged in the first light emitting area EA1 and may not be arranged in the second light emitting area EA2 and the third light emitting area EA3. In addition, the second light emitting layer may be arranged in the second light emitting area EA2 and may not be arranged in the first light emitting area EA1 and the third light emitting area EA3. In addition, the third light emitting layer may be arranged in the third light emitting area EA3 and may not be arranged in the first light emitting area EA1 and the second light emitting area EA2. In this case, first to third color filters CF1, CF2, and CF3 of the optical layer OPL may be omitted.

The second electrode CAT may be located on the light emitting stack IL. The second electrode CAT may be located on the third stack layer IL3 in each of the plurality of trenches TRC. The second electrode CAT may include or be formed of a transparent conductive material (TCO) such as ITO or IZO capable of transmitting light, or a semi-transmissive conductive material such as magnesium (Mg), silver (Ag), or an alloy of magnesium (Mg) and silver (Ag). In an embodiment where the second electrode CAT includes or is formed of a semi-transmissive conductive material, light light-emitting efficiency may be increased in each of the first to third sub-pixels SP1, SP2, and SP3 by micro cavities.

The encapsulation layer TFE may be located on the display element layer EML. The encapsulation layer TFE may include one or more inorganic films TFE1 and TFE2 to prevent oxygen or moisture from permeating into the display element layer EML. A first encapsulation inorganic film TFE1 may be located on the second electrode CAT, and a second encapsulation inorganic film TFE2 may be located on the first encapsulation inorganic film TFE1. The first encapsulation inorganic film TFE1 and the second encapsulation inorganic film TFE2 may be formed as multiple films in which one or more inorganic films of a silicon nitride layer (SiNx), a silicon oxynitride layer (SiON), a silicon oxide layer (SiOx), a titanium oxide layer (TiOx), and an aluminum oxide layer (AlOx) are alternately stacked.

In addition, the encapsulation layer TFE may include at least one organic film to protect the display element layer EML from foreign substances such as dust. In an embodiment, for example, at least one organic film of the encapsulation layer TFE may be arranged between the first encapsulation inorganic film TFE1 and the second encapsulation inorganic film TFE2. At least one organic film of the encapsulation layer TFE may be a monomer. Alternatively, at least one organic film of the encapsulation layer TFE may be an organic film including or made of an acrylic resin, an epoxy resin, a phenolic resin, a polyamide resin, or a polyimide resin.

An adhesive layer ADL may be a layer for adhering the encapsulation layer TFE and the optical layer OPL. The adhesive layer ADL may be a double-sided adhesive. In addition, the adhesive layer ADL may be a transparent adhesive such as a transparent adhesive or a transparent adhesive resin.

The optical layer OPL includes a plurality of color filters CF1, CF2, and CF3, a plurality of lenses LNS, and a filling layer FIL. The plurality of color filters CF1, CF2, and CF3 may include first to third color filters CF1, CF2, and CF3. The first to third color filters CF1, CF2, and CF3 may be located on the adhesive layer ADL.

The first color filter CF1 may overlap the first light emitting area EA1 of the first sub-pixel SP1. The first color filter CF1 may transmit light of a first color, that is, light in a blue wavelength band. The red wavelength band may be about 370 nm to about 460 nm. Therefore, the first color filter CF1 may transmit light of a first color among light emitted from the first light emitting area EA1.

The second color filter CF2 may overlap the second light emitting area EA2 of the second sub-pixel SP2. The second color filter CF2 may transmit light of a second color, that is, light in a green wavelength band. The green wavelength band may be about 480 nm to about 560 nm. Therefore, the second color filter CF2 may transmit light of a second color among light emitted from the second light emitting area EA2.

The third color filter CF3 may overlap the third light emitting area EA3 of the third sub-pixel SP3. The third color filter CF3 may transmit light of a third color, that is, light in a red wavelength band. The red wavelength band may be about 600 nm to about 750 nm. Therefore, the third color filter CF3 may transmit light of a third color among light emitted from the third light emitting area EA3.

Each of the plurality of lenses LNS may be located on each of the first color filter CF1, the second color filter CF2, and the third color filter CF3. Each of the plurality of lenses LNS may be a structure for increasing a ratio of light directed to the front of the display device 10. Each of the plurality of lenses LNS may have a cross-sectional shape that is convex in an upward direction.

The filling layer FIL may be located on the plurality of lenses LNS. The filling layer FIL may have a predetermined refractive index such that light travels in the third direction DR3 at an interface between the plurality of lenses LNS and the filling layer FIL. In addition, the filling layer FIL may be a planarization layer. The filling layer FIL may be an organic film including or made of an acryl resin, an epoxy resin, a phenolic resin, a polyamide resin, or a polyimide resin.

The cover layer CVL may be located on the filling layer FIL. The cover layer CVL may be a glass substrate or a polymer resin such as resin. In an embodiment where the cover layer CVL is a glass substrate, the cover layer CVL may be attached onto the filling layer FIL. In such an embodiment, the filling layer FIL may serve to adhere the cover layer CVL. In an embodiment where the cover layer CVL is a glass substrate, the cover layer CVL may serve as an encapsulation substrate. In an embodiment where the cover layer CVL is a polymer resin such as resin, the cover layer CVL may be directly applied on the filling layer FIL.

The polarizing plate may be located on one surface of the cover layer CVL. The polarizing plate may be a structure for preventing deterioration in visibility due to reflection of external light. The polarizing plate may include a linear polarizing plate and a phase retardation film. In an embodiment, for example, the phase retardation film may be a λ/4 (quarter-wave) plate, but the embodiment of the disclosure is not limited thereto. In an embodiment, where deterioration in visibility due to reflection of external light is sufficiently improved by the first to third color filters CF1, CF2, and CF3, the polarizing plate may also be omitted.

FIG. 16 is a cross-sectional view taken along line I1-I1′ of FIG. 13, showing another embodiment of the display panel.

The embodiment of FIG. 16 is substantially the same as the embodiment of FIG. 15 except that the first electrode AND of each of the light emitting elements LE is electrically connected by being in contact with a side surface of a connection electrode ANC connected to the eighth conductive layer ML8, and that the trench TRC is omitted, and instead, a third pixel defining film PDL3 and a fourth pixel defining film PDL4 have a cross-sectional structure in a shape of an eaves or a mushroom shape. Hereinafter, any repetitive detailed description of the same or like elements of the embodiment of FIG. 16 as those of the embodiment of FIG. 15 will be omitted or simplified.

Referring to FIG. 16, in an embodiment, a plurality of connection electrodes ANC may be respectively located on first portions AA1 of the ninth insulating film INS9. Each of the plurality of connection electrodes ANC may be located on the first portion AA1 of the ninth insulating film INS9 corresponding thereto. The plurality of connection electrodes ANC may include or be formed of an alloy including at least one selected from copper (Cu), aluminum (Al), tungsten (W), molybdenum (Mo), chromium (Cr), gold (Au), titanium (Ti), nickel (Ni), and neodymium (Nd), or transparent conductive oxide. For example, the plurality of connection electrodes ANC may include titanium (Ti), titanium nitride (TiN), indium tin oxide (ITO), or indium zinc oxide (IZO), but the embodiment of the disclosure is not limited thereto.

A plurality of reflective electrodes RL may be respectively located on the plurality of connection electrodes ANC. Each of the plurality of reflective electrodes RL may be located on the connection electrode ANC corresponding thereto. The plurality of reflective electrodes RL may include or be formed of at least one selected from copper (Cu), aluminum (Al), tungsten (W), molybdenum (Mo), chromium (Cr), gold (Au), titanium (Ti), nickel (Ni), and neodymium (Nd), or an alloy including any one thereof. In an embodiment, for example, each of the plurality of reflective electrodes RL may include aluminum (Al) having high reflectivity.

A plurality of optical auxiliary films OAL may be respectively located on the plurality of reflective electrodes RL. Each of plurality of optical auxiliary films OAL may be located on the reflective electrode RL corresponding thereto. The plurality of optical auxiliary films OAL may include or be formed of an inorganic film including silicon oxide (SiOₓ), but the embodiment of the disclosure is not limited thereto.

A step layer STPL may be located on the reflective electrode RL in each of the first light emitting area EA1 and the third light emitting area EA3, and the optical auxiliary film OAL may be located on the step layer STPL. In the second light emitting area EA2, only the optical auxiliary film OAL may be located on the reflective electrode RL. The thicknesses of the optical auxiliary film OAL in the first light emitting area EA1, the second light emitting area EA2, and the third light emitting area EA3 may be substantially the same.

Due to the step layer STPL, a distance between the reflective electrode RL and the first electrode AND in the first light emitting area EA1 and the third light emitting area EA3 may be greater than a distance between the reflective electrode RL and the first electrode AND in the second light emitting area EA2. The thickness of the step layer STPL and the thickness of the optical auxiliary film OAL may be set by considering the wavelength and resonance distance of light emitted from the first stack layer IL1 of the light emitting stack IL and the wavelength and resonance distance of light emitted from the second stack layer IL2 thereof.

Each of the light emitting elements LE may include a first electrode AND, a light emitting stack IL, and a second electrode CAT.

The first electrode AND of each of the light emitting elements LE may be located on the optical auxiliary film OAL corresponding thereto. Since the connection electrode ANC, the reflective electrode RL, and the optical auxiliary film OAL are sequentially stacked, the first electrode AND of each of the light emitting elements LE may be located on upper and side surfaces of the optical auxiliary film OAL, a side surface of the reflective electrode RL, and a side surface of the connection electrode ANC. As a result, the first electrode AND of each of the light emitting elements LE may be electrically connected by being in contact with the side surface of the reflective electrode RL and the side surface of the connection electrode ANC. Therefore, since the mask process may be reduced compared to a case where the first electrode AND of each of the light emitting elements LE is connected to the exposed reflective electrode RL through a through hole defined or formed through the optical auxiliary film OAL, manufacturing costs may be reduced and manufacturing efficiency may be increased.

The first electrode AND of each of the light emitting elements LE may be connected to the drain area DA or the source area SA of the pixel transistor PTR through the connection electrode ANC, the first to ninth vias VA1 to VA9, the first to eighth conductive layers ML1 to ML8, and the contact terminal CTE.

The ninth insulating film INS9 may include a first portion AA1 that overlaps the connection electrode ANC in the third direction DR3 and a second portion AA2 that does not overlap the connection electrode ANC in the third direction DR3. A thickness of the first portion AA1 and a thickness of the second portion AA2 of the ninth insulating film INS9 may be substantially the same as each other.

Alternatively, the thickness of the first portion AA1 of the ninth insulating film INS9 may be greater than the thickness of the second portion AA2. In such an embodiment, a side surface of the first portion AA1 of the ninth insulating film INS9 may be exposed, and the first electrode AND of each of the light emitting elements LE may be located on the exposed side surface of the first portion AA1 of the ninth insulating film INS9.

The first electrode AND of each of the light emitting elements LE may include or be formed of at least one selected from copper (Cu), aluminum (Al), tungsten (W), molybdenum (Mo), chromium (Cr), gold (Au), titanium (Ti), nickel (Ni), and neodymium (Nd), or an alloy including any one thereof, or a transparent conductive oxide. For example, the first electrode AND of each of light emitting elements LE may include titanium nitride (TiN), indium tin oxide (ITO), or indium zinc oxide (IZO), but the embodiment of the disclosure is not limited thereto.

The pixel defining film PDL may be located on a partial area of the first electrode AND of each of the light emitting elements LE. The pixel defining film PDL may cover an edge of the first electrode AND of each of the light emitting elements LE. The pixel defining film PDL may partition the first light emitting areas EA1, the second light emitting areas EA2, and the third light emitting areas EA3.

The pixel defining film PDL may include first to fourth pixel defining films PDL1, PDL2, PDL3, and PDL4.

The first pixel defining film PDL1 may be located on the first electrode AND of each of the light emitting elements LE. Specifically, the first pixel defining film PDL1 may cover a portion of an upper surface of the first electrode AND located on the optical auxiliary film OAL. In addition, the first pixel defining film PDL1 may cover the first electrode AND located on the side surface of the connection electrode ANC, the side surface of the reflective electrode RL, and the side surface of the optical auxiliary film OAL. The first pixel defining film PDL1 may be located on an upper surface of the second portion AA2 of the ninth insulating film INS9.

A planarization film PNS is a film for planarizing the steps (or stepped structures) caused by the connection electrode ANC, the reflective electrode RL, and the optical auxiliary film OAL.

The planarization film PNS may be located on the first pixel defining film PDL1 that covers the first electrode AND located on the side surface of the connection electrode ANC, the side surface of the reflective electrode RL, and the side surface of the optical auxiliary film OAL. The planarization film PNS may be located on the first pixel defining film PDL1 located on the second portion AA2 of the ninth insulating film INS9.

The planarization film PNS may be arranged between the connection electrodes ANC adjacent to each other in the first direction DR1 or the second direction DR2. The planarization film PNS may be arranged between the reflective electrodes RL adjacent to each other in the first direction DR1 or the second direction DR2. The planarization film PNS may be arranged between the optical auxiliary films OAL adjacent to each other in the first direction DR1 or the second direction DR2.

While there is no step layer STPL in the second light emitting area EA2, there is a step layer STPL in each of the first light emitting area EA1 and the third light emitting area EA3. As a result, the height of the connection electrode ANC, the reflective electrode RL, and the optical auxiliary film OAL in the second light emitting area EA2 may be smaller than the height of the connection electrode ANC, the reflective electrode RL, the step layer STPL, and the optical auxiliary film OAL in each of the first light emitting area EA1 and the third light emitting area EA3. Therefore, the planarization film PNS may cover the upper surface of the first pixel defining film PDL1 located on the upper surface of the first electrode AND arranged in the second light emitting area EA2.

In an embodiment, an upper surface of the planarization film PNS may be flatly connected to the upper surface of the first electrode AND arranged in the first light emitting area EA1 and the third light emitting area EA3. That is, the planarization film PNS may not cover the upper surface of the first pixel defining film PDL1 located on the upper surface of the first electrode AND arranged in each of the first light emitting area EA1 and the third light emitting area EA3.

The second pixel defining film PDL2 may be located on the first pixel defining film PDL1 and the planarization film PNS, the third pixel defining film PDL3 may be located on the second pixel defining film PDL2, and the fourth pixel defining film PDL4 may be located on the third pixel defining film PDL3. The first pixel defining film PDL1 and the third pixel defining film PDL3 include or are formed of an inorganic film including silicon nitride (SiNx), while the second pixel defining film PDL2, the fourth pixel defining film PDL4, and the planarization film PNS may include or be formed of an inorganic film including silicon oxide (SiOx). As the first pixel defining film PDL1 includes or is formed of a different material from the planarization film PNS, the first pixel defining film PDL1 may serve as a stopper in a process of chemically and mechanically polishing the planarization film PNS.

In an embodiment where the planarization film PNS and the second pixel defining film PDL2 include or are formed of a same inorganic film including silicon oxide (SiOx), the planarization film PNS and the second pixel defining film PDL2 may be formed as a single film.

Since a length of the third pixel defining film PDL3 in one direction is smaller than a length of the fourth pixel defining film PDL4 in one direction, a lower surface of the fourth pixel defining film PDL4 may be exposed without being covered by the third pixel defining film PDL3. That is, the third pixel defining film PDL3 and the fourth pixel defining film PDL4 may have a cross-sectional structure in a shape of an eaves or a mushroom shape.

The light emitting stack IL may be located on the first electrodes AND and the pixel defining film PDL. The light emitting stack IL may include a first stack layer IL1 and a second stack layer IL2 that emit different lights. In an embodiment where the light emitting stack IL has a two-tandem structure, one of the first stack layer IL1 and the second stack layer IL2 may emit light including a wavelength range of one of the first light, the second light, and the third light, and the remaining one may emit light that includes the wavelength ranges of the other two lights. In an embodiment, for example, the first stack layer IL1 may emit light that includes a wavelength range of the first light and a wavelength range of the third light, and the second stack layer IL2 may emit light that includes a wavelength range of the second light. Here, the first light may be light of a blue wavelength band, the second light may be light of a green wavelength band, and the third light may be light of a red wavelength band.

A charge generation layer for supplying charges to the second stack layer IL2 and supplying electrons to the first stack layer IL1 may be arranged between the first stack layer IL1 and the second stack layer IL2. The charge generation layer may include an n-type charge generation layer that supplies electrons to the first stack layer IL1 and a p-type charge generation layer that supplies holes to the second stack layer IL2. The n-type charge generation layer may include a dopant of a metallic material.

In an embodiment where the first stack layer IL1 is not formed on the exposed lower surface of the fourth pixel defining film PDL4 that is not covered by the third pixel defining film PDL3, the first stack layer IL1 may be disconnected by the cross-sectional structure in the shape of an eaves or the mushroom shape by the third pixel defining film PDL3 and the fourth pixel defining film PDL4. In such an embodiment, the first hole transporting layer of the first stack layer IL1 and the charge generation layer CGL arranged between the first stack layer IL1 and the second stack layer IL2 may also be disconnected. In an embodiment, as illustrated in FIG. 16, the second stack layer IL2 may be connected without being disconnected, but the second hole transporting layer of the second stack layer IL2 may be disconnected, and the second electron transporting layer of the second stack layer IL2 may be connected without being disconnected. Therefore, it is possible to effectively prevent leakage current from flowing between the light emitting areas EA1, EA2, and EA3 adjacent to each other through the first hole transporting layer of the first stack layer IL1, the second hole transporting layer of the second stack layer IL2, and the charge generation layer CGL. Therefore, it is possible to effectively prevent the light emitting stacks IL in the light emitting areas EA1, EA2, and EA3 adjacent to each other from being affected by the current and emitting light other than the originally intended light.

FIG. 16 illustrates an embodiment where the light emitting stack IL has the two-tandem structure in which the light emitting stack IL includes two stack layers IL1 and IL2, but the embodiment of the disclosure is not limited thereto. In an embodiment, for example, the light emitting stack IL may have a three-tandem structure including three stack layers as illustrated in FIG. 15. In such an embodiment, by adjusting the height of the third pixel defining film PDL3, the charge generation layer between the first stack layer IL1 and the second stack layer IL2, and the charge generation layer between the second stack layer IL2 and the third stack layer IL3 may be designed to be disconnected. Alternatively, as illustrated in FIG. 15, a trench defined or formed through the first pixel defining film PDL1, planarization film PNS, the second pixel defining film PDL2, and the third pixel defining film PDL3 may be added. In such an embodiment, the trench TRC may extend through at least a portion of the ninth insulating film INS9, but the embodiment of the disclosure is not limited thereto.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display device comprising:
a light source which provides light;
a plurality of first nanostructures which collimates the light from the light source and converts a light path of the light from the light source;
a light guide portion which totally reflects light incident thereon from the plurality of first nanostructures in a way such that the light thereon travels from one end to another end thereof;
a spatial light modulator which modulates a phase of light incident thereon from the light guide portion and outputs the light having the phase modulated thereby; and
a plurality of second nanostructures which collimates light incident thereon from the light guide portion and converts a light path of the light incident thereon to provide the light incident thereon to the spatial light modulator.

2. The display device of claim 1, wherein the plurality of first nanostructures have a first width, a first height, and a first spacing.

3. The display device of claim 1, wherein the plurality of second nanostructures have a second width, a second height, and a second spacing.

4. The display device of claim 1, wherein a length of a second area, in which the plurality of second nanostructures are arranged, in a first direction is greater than a length of a first area, in which the plurality of first nanostructures are arranged, in the first direction.

5. The display device of claim 4, wherein a length of the second area, in which the plurality of second nanostructures are arranged, in a second direction orthogonal to the first direction is the same as a length of the first area, in which the plurality of first nanostructures are arranged, in the second direction.

6. The display device of claim 1, wherein the light source is an organic light emitting diode-on-silicon display device including an organic light emitting layer disposed on a first semiconductor substrate.

7. The display device of claim 1, wherein the light source includes:
a first light source which provides first light of a first color;
a second light source which provides second light of a second color; and
a third light source which provides third light of a third color.

8. The display device of claim 7, wherein each of the first light source, the second light source and the third light source is an organic light emitting diode-on-silicon display device including an organic light emitting layer disposed on a first semiconductor substrate.

9. The display device of claim 7, wherein the plurality of first nanostructures include:
a plurality of first sub-nanostructures overlapping the first light source, wherein the plurality of first sub-nanostructures collimates the first light emitted from the first light source and converts a light path of the first light emitted from the first light source;
a plurality of second sub-nanostructures overlapping the second light source, wherein the plurality of second sub-nanostructures collimates the second light emitted from the second light source and converts a light path of the second light emitted from the second light source; and
a plurality of third sub-nanostructures overlapping the third light source, wherein the plurality of third sub-nanostructures collimates the third light emitted from the third light source and converts a light path of the third light emitted from the third light source.

10. The display device of claim 9, wherein the plurality of first sub-nanostructures and the plurality of second sub-nanostructures are different from each other.

11. The display device of claim 10, wherein the plurality of third sub-nanostructures are different from the plurality of first sub-nanostructures and the plurality of second sub-nanostructures.

12. The display device of claim 1, wherein the spatial light modulator is a liquid crystal-on-silicon display device including a liquid crystal layer disposed on a second semiconductor substrate.

13. The display device of claim 1, wherein the spatial light modulator includes:
a first spatial light modulator which modulates a phase of first light;
a second spatial light modulator which modulates a phase of second light; and
a third spatial light modulator which modulates a phase of third light.

14. The display device of claim 13, wherein each of the first spatial light modulator, the second spatial light modulator and the third spatial light modulator is a liquid crystal-on-silicon display device including a liquid crystal layer disposed on a second semiconductor substrate.

15. The display device of claim 13, wherein the plurality of second nanostructures include:
a plurality of fourth sub-nanostructures overlapping the first spatial light modulator, wherein the plurality of fourth sub-nanostructures collimates the first light incident thereon from the light guide portion and converts a light path of the first light incident thereon to provide the first light incident thereon to the first spatial light modulator;
a plurality of fifth sub-nanostructures overlapping the second spatial light modulator, wherein the plurality of fifth sub-nanostructures collimates the second light incident thereon from the light guide portion and converts a light path of the second light incident thereon to provide the second light incident thereon to the second spatial light modulator; and
a plurality of sixth sub-nanostructures overlapping the third spatial light modulator, wherein the plurality of sixth sub-nanostructures collimates the third light incident thereon from the light guide portion and converts a light path of the third light incident thereon to provide the third light incident thereon to the third spatial light modulator.

16. The display device of claim 15, wherein the plurality of fourth sub-nanostructures and the plurality of fifth sub-nanostructures are different from each other.

17. The display device of claim 16, wherein the plurality of sixth sub-nanostructures are different from the plurality of fourth sub-nanostructures and the plurality of fifth sub-nanostructures.

18. The display device of claim 1, wherein the light guide portion extends in a first direction,
the light source is arranged to be adjacent to one side of the light guide portion in the first direction, and
the spatial light modulator is arranged to be adjacent to another side of the light guide portion in the first direction.

19. The display device of claim 1, wherein the light guide portion includes:
a first extension portion extending in a first direction;
a second extension portion extending in a third direction intersecting the first direction; and
a reflector arranged in an area where one side of the first extension portion and one side of the second extension portion meet.

20. An electronic device comprising:
a lens; and
a display device which displays an image to a user's single eye through the lens,
wherein the display device includes:
a light source which provides light;
a plurality of first nanostructures which collimates the light from the light source and converts a light path of the light from the light source;
a light guide portion which totally reflects light incident thereon from the plurality of first nanostructures in a way such that the light incident thereon travels from one end to another end thereof;
a spatial light modulator which modulate a phase of light incident thereon from the light guide portion and outputs the light having the phase modulated thereby; and
a plurality of second nanostructures which collimates light incident thereon from the light guide portion and converts a light path of the light incident thereon to provide the light thereon to the spatial light modulator.
